(19) United States
(12) Patent Application Publication
(10) Pub. No.: US 2026/0262279 A1
(43) Pub. Date: Sep. 3, 2026

(54) SILICON CARBIDE SEMICONDUCTOR DEVICE AND METHOD OF MANUFACTURING SILICON CARBIDE SEMICONDUCTOR DEVICE

(71) Applicant: FUJI ELECTRIC CO., LTD., Kawasaki-shi (JP)

(72) Inventors: Makoto UTSUMI, Matsumoto-city (JP); Akimasa KINOSHITA, Tokyo (JP); Naoyuki OHSE, Matsumoto-city (JP)

(73) Assignee: FUJI ELECTRIC CO., LTD., Kawasaki-shi (JP)

(21) Appl. No.: 19/656,854

(22) Filed: Apr. 23, 2026

Related U.S. Application Data
(63) Continuation of application No. PCT/JP2025/004155, filed on Feb. 7, 2025.

(30) Foreign Application Priority Data
May 29, 2024 (JP) 2024-087536

(51) Int. Cl. H10D 84/00; H10D 8/00; H10D 8/01; H10D 8/25; H10D 30/01; H10D 30/66; H10D 62/10; H10D 62/60; H10D 62/83; H10D 62/832; H10D 62/834

(52) U.S. Cl. CPC H10D 84/143; H10D 8/022; H10D 8/045; H10D 8/25; H10D 8/411; H10D 30/0297; H10D 30/668; H10D 62/103; H10D 62/60; H10D 62/83; H10D 62/8325; H10D 62/834; H10D 84/148

(57) ABSTRACT

A semiconductor device, including: a semiconductor substrate containing silicon carbide; a semiconductor device element provided on the semiconductor substrate; a poly-silicon layer provided on a main surface of the semiconductor substrate via an insulating film, the poly-silicon layer including a p-type first poly-silicon layer and an n-type second poly-silicon layer forming a pn junction therebetween; and a diode formed by the pn junction. The second poly-silicon layer contains phosphorus or antimony as a donor, and is so configured that a sheet resistance thereof at 25 degrees C is not less than 80 Ω/□ but not more than 400 Ω/□.

### CROSS REFERENCE TO RELATED APPLICATIONS

This is a continuation application of International Application PCT/JP2025/004155 filed on February 7, 2025 which claims priority from a Japanese Patent Application No. 2024-087536 filed on May 29, 2024, the contents of which are incorporated herein by reference.

### BACKGROUND OF THE INVENTION

### 1. Field of the Invention

Embodiments of the disclosure relate to a silicon carbide semiconductor device and a method of manufacturing a silicon carbide semiconductor device.

### 2. Description of the Related Art

Japanese Patent No. 6132032 describes a technique in which a pn junction diode formed by ion-implanting dopants into a polycrystalline silicon layer provided on a semiconductor substrate via an insulating film is used as a temperature detecting diode. A similar technique is also described in Japanese Patent No. 6107937.

### SUMMARY OF THE INVENTION

According to an embodiment of the present disclosure, a semiconductor device includes: a semiconductor substrate containing silicon carbide; a semiconductor device element provided on the semiconductor substrate; a poly-silicon layer provided on a main surface of the semiconductor substrate via an insulating film, the poly-silicon layer including a p-type first poly-silicon layer and an n-type second poly-silicon layer forming a pn junction therebetween; and a diode formed by the pn junction. The second poly-silicon layer contains phosphorus or antimony as a donor, and is so configured that a sheet resistance thereof at 25 degrees C is not less than 80 Ω/□ but not more than 400 Ω/□.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout of a temperature sensing portion of a silicon carbide semiconductor device according to a first embodiment, as viewed from a front surface side of a semiconductor substrate.

FIG. 2A is a cross-sectional view of a structure taken along a cutting line A1-A2 in FIG. 1.

FIG. 2B is a circuit diagram depicting an equivalent circuit of the temperature sensing portion in FIG. 1.

FIG. 3 is a plan view depicting a layout example of the silicon carbide semiconductor device according to the first embodiment, as viewed from the front surface side of the semiconductor substrate.

FIG. 4 is a cross-sectional view depicting an example of a structure taken along a cutting line B1-B2-B3 in FIG. 3.

FIG. 5 is a flowchart depicting an outline of a method of manufacturing the silicon carbide semiconductor device according to the first embodiment.

FIG. 6 is a characteristic diagram depicting results of experimental verification of temperature dependence of a temperature coefficient of the temperature sensing portion.

FIG. 7 is a characteristic diagram depicting results of experimental verification of the temperature dependence of the temperature coefficient of the temperature sensing portion.

FIG. 8 is a characteristics diagram depicting a result of experimentally verifying a relationship between a temperature coefficient and a sheet resistance of the temperature sensing portion.

FIG. 9 is a table depicting results of experimental verification of the relationship between a dose of ion implantation at steps S4 and S7 in FIG. 5 and the activation temperature of the heat treatment at step S11.

FIG. 10 is a table depicting results of experimental verification of the relationship between a dose of ion implantation at steps S4 and S7 in FIG. 5 and the activation temperature of the heat treatment at step S11.

FIG. 11 is a characteristics diagram depicting a result of experimental verification of temperature dependence of the sheet resistance of a p-type anode region of the temperature sensing portion.

FIG. 12 is a characteristics diagram depicting a result of experimental verification of the temperature dependence of the sheet resistance of the n-type cathode region of the temperature sensing portion.

FIG. 13 is a cross-sectional view depicting a structure of a silicon carbide semiconductor device of a reference example.

FIG. 14 is a cross-sectional view schematically depicting a state of dielectric breakdown in FIG. 13.

FIG. 15 is a cross-sectional view schematically depicting a state of dielectric breakdown in FIG. 13.

FIG. 16 is a plan view depicting a layout of the temperature sensing portion of a silicon carbide semiconductor device according to a second embodiment, as viewed from the front surface side of the semiconductor substrate.

FIG. 17A is a cross-sectional view depicting a structure taken along a cutting line C1-C2 in FIG. 16. FIG. 17B is a circuit diagram depicting an equivalent circuit of the temperature sensing portion of FIG. 16.

FIG. 18 is a plan view depicting a layout example of the silicon carbide semiconductor device according to the second embodiment, as viewed from the front surface side of the semiconductor substrate.

FIG. 19 is a plan view depicting a layout of the temperature sensing portion of a silicon carbide semiconductor device according to a third embodiment, as viewed from the front surface side of the semiconductor substrate.

FIG. 20A is a cross-sectional view depicting a structure along a cutting line D1-D2 in FIG. 19.

FIG. 20B is a circuit diagram depicting an equivalent circuit of the temperature sensing portion in FIG. 19.

FIG. 21 is a plan view depicting a layout of the temperature sensing portion of the silicon carbide semiconductor device according to a fourth embodiment, as viewed from the front surface side of the semiconductor substrate.

FIG. 22A is a cross-sectional view depicting a structure taken along cutting line E1-E2 in FIG. 21.

FIG. 22B is a cross-sectional view depicting a structure taken along cutting line E3-E4 in FIG. 21.

FIG. 22C is a circuit diagram depicting an equivalent circuit of the temperature sensing portion in FIG. 21.

FIG. 23 is a plan view depicting a layout of the temperature sensing portion of a silicon carbide semiconductor device according to a fifth embodiment, as viewed from the front surface side of the semiconductor substrate.

FIG. 24 is a circuit diagram depicting an equivalent circuit of the temperature sensing portion in FIG. 23.

FIG. 25 is a plan view depicting a layout example of the silicon carbide semiconductor device according to the fifth embodiment, as viewed from the front surface side of the semiconductor substrate.

FIG. 26 is a plan view depicting a layout of the temperature sensing portion of a silicon carbide semiconductor device according to a sixth embodiment, as viewed from the front surface side of the semiconductor substrate.

FIG. 27A is a cross-sectional view depicting a structure, along a cutting line G1-G2 in FIG. 26.

FIG. 27B is a circuit diagram depicting an equivalent circuit of the temperature sensing portion in FIG. 26.

FIG. 28 is a plan view depicting a layout example of the silicon carbide semiconductor device according to the sixth embodiment, as viewed from the front surface side of the semiconductor substrate.

FIG. 29 is a plan view depicting a layout of the temperature sensing portion of a silicon carbide semiconductor device according to a seventh embodiment, as viewed from the front surface side of the semiconductor substrate.

FIG. 30A is a cross-sectional view depicting a structure taken along cutting line H3-H4 in FIG. 29.

FIG. 30B is a circuit diagram depicting an equivalent circuit of the temperature sensing portion in FIG. 29.

### DETAILED DESCRIPTION OF THE INVENTION

In Japanese Patent No. 6132032 and Japanese Patent No. 6107937, the temperature detection accuracy of the temperature detecting diode is reduced due to the temperature dependence of the temperature coefficient of the temperature detecting diode, and the temperature of the semiconductor device element formed on the same semiconductor substrate as the temperature detecting diode may not be accurately detected.

An outline of embodiments of the present disclosure is described. (1) A silicon carbide semiconductor device according to one aspect of the present disclosure is as follows. A semiconductor device element having a predetermined element structure is provided in a semiconductor substrate containing silicon carbide. A poly-silicon layer is provided on a first main surface of the semiconductor substrate via an insulating film. A portion of the poly-silicon layer is a p-type first poly-silicon layer. A portion of the poly-silicon layer is an n-type second poly-silicon layer. A diode is formed by a pn junction between the first poly-silicon layer and the second poly-silicon layer. The second poly-silicon layer includes phosphorus or antimony as a donor. A sheet resistance of the second poly-silicon layer at 25 degrees C is not less than 80Ω/□ but not more than 400Ω/□.

According to the above disclosure, the temperature dependence of the sheet resistance of the second poly-silicon layer can be reduced. Thus, the temperature dependence of the rate of change of the difference in potential between both ends of the diode with respect to the temperature change of the semiconductor device element can be reduced, whereby the temperature detection accuracy by the diode can be improved.

(2) In the silicon carbide semiconductor device according to (1), the first poly-silicon layer contains boron or indium as an acceptor. The sheet resistance of the first poly-silicon layer at 25 degrees C is not less than 50Ω/□ but not more than 170Ω/□.

According to the above disclosure, the temperature dependence of the sheet resistance of the second poly-silicon layer can be reduced. Thus, the temperature dependence of the rate of change of the difference in potential between both ends of the diode with respect to the temperature change of the semiconductor device element can be further reduced, whereby the temperature detection accuracy by the diode can be further improved.

(3) In the silicon carbide semiconductor device according to (1) or (2), the poly-silicon layer may have a thickness of not less than 300 nm but not more than 600 nm.

The above disclosure is applicable to an existing diode formed of a poly-silicon layer.

(4) In the silicon carbide semiconductor device according to any one of (1) to (3) described above, the diode may be a temperature sensing portion that detects the temperature of the semiconductor device element based on the rate of change of the difference in potential between both ends of the diode with respect to the temperature change of the semiconductor device element.

According to the disclosure described above, since the temperature of the semiconductor device element can be accurately detected, destruction of the semiconductor device element can be prevented.

(5) In the silicon carbide semiconductor device according to the present disclosure, in any one of (1) to (4) described above, the semiconductor device element may be a MOSFET for use in vehicles.

According to the above disclosure, the present invention is useful for a switching element for in-vehicle when there is a period during which the switching element operates in a low-temperature state with almost no temperature rise at an initial stage of engine start.

(6) A method of manufacturing a silicon carbide semiconductor device according to one aspect of the present disclosure is as follows. As a first process, a semiconductor device element having a predetermined element structure is formed in a semiconductor substrate containing silicon carbide. As a second process, a poly-silicon layer is formed on a first main surface of the semiconductor substrate via an insulating film. As a third process, a first poly-silicon layer is formed by ion-implanting a p-type dopant into the poly-silicon layer. As a fourth process, a second poly-silicon layer is formed by ion-implanting an n-type dopant into the poly-silicon layer to form a diode by a pn junction between the first poly-silicon layer and the second poly-silicon layer. As a fifth process, the p-type dopant and the n-type dopant as an acceptor and a donor, respectively, are activated by a heat treatment. In the fourth process, phosphorus is used as the n-type dopant and a net dose amount of ion implantation is set to not less than 1.0×10¹⁵/cm² but not more than 1.0×10¹⁶/cm², or antimony is used as the n-type dopant and the net dose amount of ion implantation is set to not less than 1.5×10¹⁵/cm² but not more than 2.5×10¹⁵/cm².

According to the above disclosure, the sheet resistance of the second poly-silicon layer can be set within the above range.

(7) In the method of manufacturing the silicon carbide semiconductor device according to (6), in the third process, boron may be used as the p-type dopant and a net dose amount of ion implantation may be set to 7.0×10¹⁴/cm² or more and 1.0×10¹⁶/cm² or less, or indium may be used as the p-type dopant and a net dose amount of ion implantation may be set to 4.0×10¹⁴/cm² or more and 7.0×10¹⁴/cm² or less.

According to the above disclosure, the sheet resistance of the first poly-silicon layer can be set within the above range.

(8) In the method of manufacturing the silicon carbide semiconductor device according to (6) or (7) described above, in the fifth process, a temperature of the heat treatment may be within a range of 1050 degrees C to 1200 degrees C.

According to the above disclosure, the activation rate of the p-type dopant and the n-type dopant can be increased.

(9) In the method of manufacturing the silicon carbide semiconductor device according to the present disclosure, in any one of (6) to (8) described above, in the second process, a thickness of the poly-silicon layer may be not less than 300 nm but not more than 600 nm.

The above disclosure is applicable to an existing diode formed of a poly-silicon layer.

(10) In the method of manufacturing the silicon carbide semiconductor device according to any one of (6) to (9), the diode may be a temperature sensing portion that detects the temperature of the semiconductor device element based on a rate of change of a difference in potential between both ends of the diode with respect to a change in the temperature of the semiconductor device element.

According to the disclosure described above, since the temperature of the semiconductor device element can be accurately detected, destruction of the semiconductor device element can be prevented.

(11) In the method of manufacturing the silicon carbide semiconductor device according to the present disclosure, in any one of (6) to (10) described above, the semiconductor device element may be a MOSFET for use in a vehicle.

According to the above disclosure, the present invention is useful for a switching element for in-vehicle use when there is a period during which the switching element operates in a low-temperature state with almost no temperature rise at the initial stage of engine start.

(12) The silicon carbide semiconductor device according to the present disclosure may further include, in any one of (1) to (5) described above, the poly-silicon layer being provided in plural apart from one another other, diodes formed respectively in the poly-silicon layers, at least one first diode among said diodes, and a second diode excluding the first diode among said diodes, where the first diode may be connected in antiparallel to the second diode or may be connected between a lowest potential point of the semiconductor device element and a cathode of the second diode.

According to the above disclosure, it is possible to arrange multiple diode portions (first and second diodes) having different functions formed by the pn junctions between the first poly-silicon layer and the second poly-silicon layer. Therefore, the degree of freedom in designing the diodes using the poly-silicon layer is increased.

(13) In the silicon carbide semiconductor device according to (12), the first diode is connected in anti-parallel to the second diode. The semiconductor device may further include a surface electrode provided on the first main surface of the semiconductor substrate and electrically connected to the lowest potential point of the semiconductor device element and the cathode of the second diode.

According to the above disclosure, since the surface electrode common to the semiconductor device element and the second diode can be provided, the number of metal wiring layers on the semiconductor substrate can be reduced.

(14) In the silicon carbide semiconductor device according to (13), the first diode may be a protective diode that conducts when a transient voltage exceeding a Zener voltage is applied and that protects the semiconductor device element from the transient voltage by drawing a current generated by the transient voltage outside the silicon carbide semiconductor device.

According to the above disclosure, since the first diode can be used as a protective diode, ESD tolerance of the silicon carbide semiconductor device can be improved.

(15) In the silicon carbide semiconductor device according to (12) above, the first diode is a bidirectional Zener diode connected between the lowest potential point of the semiconductor device element and the cathode of the second diode. The semiconductor device may further include: a front electrode provided on the first main surface of the semiconductor substrate and electrically connected to the cathode of the second diode and one anode of the first diode; and a front electrode provided on the first main surface of the semiconductor substrate and electrically connected to the lowest potential point of the semiconductor device element and the other anode of the first diode.

According to the above disclosure, since the surface electrode common to the second diode and the first diode and the surface electrode common to the semiconductor device element and the first diode can be provided, the number of metal wiring layers on the semiconductor substrate can be reduced.

(16) In the silicon carbide semiconductor device according to (15), the first diode may include two Zener diodes connected in series in opposite directions in the poly-silicon layer, and the Zener diode may be formed by a pn junction between the first poly-silicon layer and the second poly-silicon layer common to the two Zener diodes.

According to the above disclosure, a bidirectional Zener diode formed by the pn junction between the first poly-silicon layer and the second poly-silicon layer can be disposed as the first diode.

(17) In the silicon carbide semiconductor device according to (16), a dopant concentration of the first poly-silicon layer constituting the first diode may be equal to a dopant concentration of the first poly-silicon layer constituting the second diode.

According to the above disclosure, the first poly-silicon layer constituting the first diode can be formed simultaneously with the first poly-silicon layer constituting the second diode.

(18) In the silicon carbide semiconductor device according to (16), a dopant concentration of the second poly-silicon layer constituting the first diode may be equal to a dopant concentration of the second poly-silicon layer constituting the second diode.

According to the above disclosure, the second poly-silicon layer constituting the first diode can be formed simultaneously with the second poly-silicon layer constituting the second diode. The value of resistance of the first diode can be easily set by appropriately adjusting the width and length of the second poly-silicon layer constituting the first diode.

(19) In the silicon carbide semiconductor device according to (16), the first diode may be a protective diode that protects the semiconductor device element from a transient voltage exceeding a predetermined voltage by clamping the transient voltage using reverse characteristics of the Zener diode.

According to the above disclosure, since the first diode can be used as a protective diode, the ESD tolerance of the silicon carbide semiconductor device can be improved.

(20) The silicon carbide semiconductor device according to the present disclosure may further include, in any one of (12) to (17) described above, the first diode connected in antiparallel to the second diode, and the first diode connected between the lowest potential point of the semiconductor device element and the cathode of the second diode.

According to the above disclosure, it is possible to arrange multiple diode portions (first to third diodes) having different functions and formed by pn junctions between the first poly-silicon layer and the second poly-silicon layer.

(21) In the silicon carbide semiconductor device according to any one of (12) to (18), the second diode may be a temperature sensing portion that detects the temperature of the semiconductor device element based on a rate of change of a difference in potential between both ends of the second diode with respect to a temperature change of the semiconductor device element.

According to the disclosure described above, since the temperature of the semiconductor device element can be accurately detected, destruction of the semiconductor device element can be prevented.

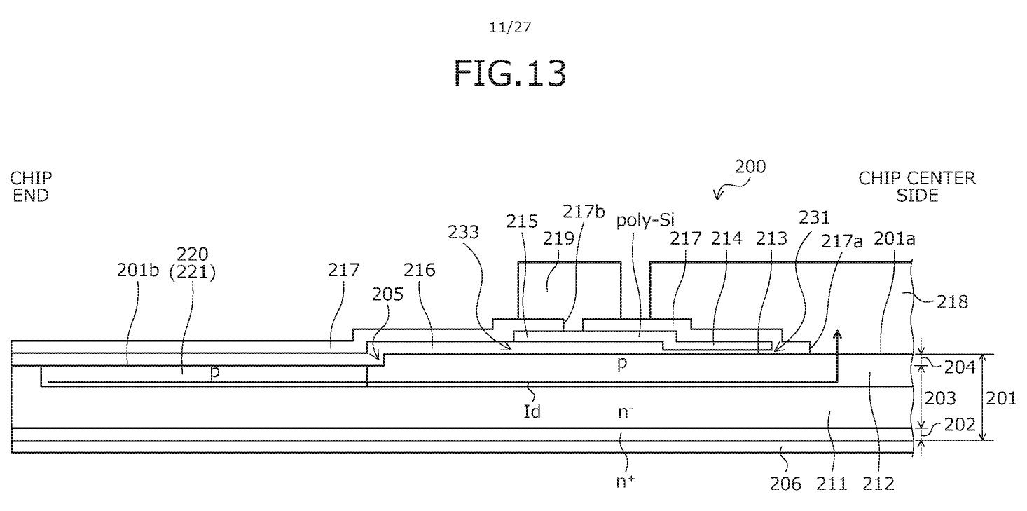

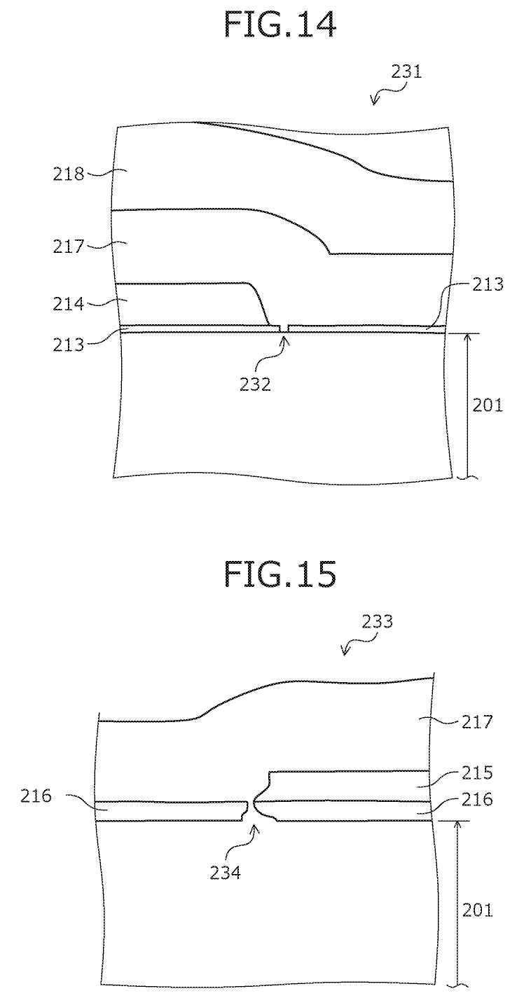

Findings underlying the present disclosure are discussed. FIG. 13 is a cross-sectional view depicting a structure of a silicon carbide semiconductor device of a reference example. FIGS. 14 and 15 are cross-sectional views schematically depicting states of dielectric breakdown in FIG. 13. A silicon carbide semiconductor device 200 of the reference example depicted in FIG. 13 is a vertical metal oxide semiconductor field effect transistor (MOSFET) including an insulated gate having a three-layer metal-oxide-semiconductor structure) including a gate poly-silicon (poly-Si) wiring layer 215 on a front surface of a semiconductor substrate 201 containing silicon carbide (SiC), via an insulating film (a gate insulating film 213 and a field oxide film 216).

The semiconductor substrate 201 is formed by growing by epitaxy, in this order on an n⁺-type starting substrate 202 containing SiC, SiC layers 203 and 204, which become an n⁻-type drift region 211 and a p-type base region 212, respectively. At a front surface (main surface on the SiC layer 204 side) of the semiconductor substrate 201, a source electrode 218 is provided in a central portion of an active region, and a gate metal wiring layer 219 is provided in an outer peripheral portion of the active region. The front surface of the semiconductor substrate 201 is entirely covered by an insulating film (the gate insulating film 213, the field oxide film 216, and the interlayer insulating film 217) except for a contact with the source electrode 218 (an electrical contact portion formed in a contact hole 217a of the interlayer insulating film 217).

The active region is provided at a center (chip center) of the semiconductor substrate 201. An insulated gate (not depicted) of the MOSFET is provided on the front surface portion 201a side of the semiconductor substrate 201 in the central portion of the active region. A region between the active region and the end (chip end) of the semiconductor substrate 201 is an edge termination region. In the edge termination region, for example, a general voltage withstanding structure 220 such as a field limiting ring (FLR), a junction termination extension (JTE) structure, or a guard ring is provided.

The p-type SiC layer 204, which is an uppermost layer of the semiconductor substrate 201, terminates closer to the chip center than is the voltage withstanding structure 220. A front surface portion 201a of the semiconductor substrate 201, closer to the chip center than is the voltage withstanding structure 220 is formed by a portion of a surface of the p-type SiC layer 204, and a front surface portion 201b of the semiconductor substrate 201 in a portion where the voltage withstanding structure 220 is provided is formed by a portion of a surface of the n⁻-type SiC layer 203. The front surface of the semiconductor substrate 201 is recessed toward the starting substrate 202 at a portion closer to the chip end than is a portion closer to the chip center with an end 205 of the SiC layer 204 as a boundary. A drain electrode 206 is provided at the entire back surface (main surface on the starting substrate 202 side) of the semiconductor substrate 201.

The gate poly-silicon wiring layer 215 and the gate metal wiring layer 219 are provided between the active region and the voltage withstanding structure 220 and surround a periphery of a contact between the source electrode 218 and the front surface portion 201a of the semiconductor substrate 201. The gate poly-silicon wiring layer 215 is provided on the front surface portion 201a of the semiconductor substrate 201 via an insulating film formed by stacking a gate insulating film 213 and a field oxide film 216. The gate electrode 214 of the MOSFET extends on the gate insulating film 213 on the front surface portion 201a of the semiconductor substrate 201 to the chip end side and is connected to the gate poly-silicon wiring layer 215.

The gate poly-silicon wiring layer 215 is covered by an interlayer insulating film 217. The gate metal wiring layer 219 is connected to the gate poly-silicon wiring layer 215 via a contact hole 217b of the interlayer insulating film 217. A p-type base region 212 constituting an insulated gate of the MOSFET extends from the active region, between the front surface portion 201a of the semiconductor substrate 201 and the n⁻-type drift region 211 immediately below the gate poly-silicon wiring layer 215. The p-type region 221 configuring the voltage withstanding structure 220 is provided between the front surface portion 201b of the semiconductor substrate 201 and the n⁻-type drift region 211 and is adjacent to the chip end side of the p-type base region 212.

In the silicon carbide semiconductor device 200 of the reference example described above, a positive voltage with respect to the source electrode 218 is applied to the drain electrode 206, and the pn junction between the p-type base region 212 and the n⁻-type drift region 211 is reverse-biased. In this state, when the voltage applied to the gate electrode 214 exceeds the gate threshold voltage, a channel (n-type inversion layer) is formed along the gate electrode 214 in a portion of the p-type base region 212 between an n⁺-type source region (not depicted) and the n⁻-type drift region 211, a current flows from an n⁺-type drain region (starting substrate 202) toward the source electrode 218 through the n⁻-type drift region 211 and the channel, whereby the MOSFET turns on.

On the other hand, when the voltage applied to the gate electrode 214 becomes less than the gate threshold voltage, since the pn junction between the p-type base region 212 and the n⁻-type drift region 211 is reverse-biased, holes in the n⁻-type drift region 211 are discharged to the source electrode 218 through the p-type base region 212 or the p-type region 221 constituting the breakdown withstanding structure 220, and electrons in the n⁻-type drift region 211 are discharged to the drain electrode 206. As a result, a depletion layer spreads in the vertical direction from the pn junction between the p-type base region 212 and the n⁻-type drift region 211 and the pn junction between the p-type region 221 and the n⁻-type drift region 211 toward both main surfaces of the semiconductor substrate 201, whereby the MOSFET is turned off.

When the MOSFET turns off, a displacement current Id flows toward the source electrode 218 through the pn junction capacitance of the MOSFET (the depletion layer capacitance formed in the pn junction between the p-type base region 212 and the n⁻-type drift region 211 and between the p-type region 221 and the n⁻-type drift region 211), the p-type region 221, and the p-type base region 212 due to a temporal change (dV/dt) in the drain-source voltage. Since dopants are difficult to diffuse in SiC, the p-type dopant to be ion-implanted for forming the p-type region in SiC is mainly aluminum (Al). The dopant level due to Al generated in the p-type SiC region is relatively deep, and the temperature dependence of the electrical conductivity increases.

At a low temperature (negative temperature of less than 0 degrees C), Al, which is a p-type dopant, becomes an acceptor and emission of holes becomes difficult, whereby the carrier concentration (hole concentration) in the p-type SiC region rapidly decreases. Therefore, the p-type SiC region is in a state close to an insulator and the sheet resistance rapidly increases. Therefore, when the displacement current Id flows during operation of the MOSFET in a low-temperature state, the potential (=current value of the displacement current Id×value of resistance of the sheet resistance of the p-type region 221 and the p-type base region 212) increases in the p-type region 221 and the p-type base region 212, and a voltage higher than expected is applied.

As a result, dielectric breakdowns 232 and 234 occur in the relatively thin insulating film immediately below the gate poly-silicon wiring layer 215, exceeding the dielectric breakdown voltage. The inventors have verified that the operation temperature of the MOSFET depicted in FIG. 13 is −40 degrees C. As a result, it was confirmed that the dielectric breakdown 232 occurred in the gate insulating film 213 immediately below the gate electrode 214 at a portion 231 in a vicinity of a contact end (sidewall of the contact hole 217a) between the semiconductor substrate 201 and the source electrode 218 (FIG. 14). Further, the inventors have confirmed that a field oxide film 216 undergoes dielectric breakdown 234 in a portion 233 under the end of the gate poly-silicon wiring layer 215 on the chip end side (FIG. 15).

At the positions of the dielectric breakdowns 232 and 234, the gate poly-silicon wiring layer 215 and the source electrode 218 are short-circuited via the p-type base region 212. Here, the thickness of the gate insulating film 213 is about 60 nm, and the thickness of the field oxide film 216 is about 500 nm. In addition, there is a possibility that the MOSFET is destroyed due to parasitic npn bipolar transistor operation using the displacement current Id as a base current. Therefore, it is necessary to take measures to reduce the displacement current Id, such as providing a temperature sensing portion (not depicted) in the semiconductor substrate 201, monitoring the temperature of the MOSFET by the temperature sensing portion, and adjusting the switching speed of the MOSFET according to the temperature of the MOSFET.

The temperature sensing portion is configured by a lateral pn junction diode formed by ion-implanting dopants into a poly-silicon layer provided on the front surface portion 201a of the same semiconductor substrate 201 as that of the MOSFET, via an insulating film. The temperature dependence of the difference in potential VF between the anode and the cathode of the temperature sensing portion (voltage drop due to the forward current flowing through the temperature sensing portion) is obtained in advance, and the difference in potential VF of the temperature sensing portion is measured during the operation of the MOSFET, whereby the temperature T of the MOSFET (front surface temperature of the front surface portion 201a of the semiconductor substrate 201) can be detected based on the temperature dependence of the difference in potential VF of the temperature sensing portion.

When a temperature coefficient α [mV/degrees C] (hereinafter, referred to as a temperature coefficient α of the temperature sensing portion) representing a rate of change of the difference in potential VF [mV] of the temperature sensing portion with respect to a change in the temperature T [degrees C] of the MOSFET is constant regardless of the temperature, a relationship between the difference in potential VF of the temperature sensing portion and the temperature T of the MOSFET can be simply represented as VF=αT. On the other hand, when the temperature coefficient α of the temperature sensing portion is temperature dependent, a deviation occurs between the temperature T of the MOSFET calculated from the above simple relational expression between the difference in potential VF of the temperature sensing portion and the temperature T of the MOSFET and the actual temperature of the MOSFET (the surface temperature of the front surface portion 201a of the semiconductor substrate 201).

The silicon carbide semiconductor device 200 using SiC as a semiconductor material is used, for example, in an in-vehicle application, and there is a period in which the silicon carbide semiconductor device 200 operates in a low-temperature state without substantially increasing in temperature at an initial stage of engine start. Therefore, the silicon carbide semiconductor device 200 has to operate in a temperature range of, for example, about −50 degrees C to 200 degrees C when formed using SiC as a semiconductor material. The temperature sensing portion has to have accurate temperature detection in an operating temperature range of the silicon carbide semiconductor device 200 on which the temperature sensing portion is mounted. However, Japanese Patent No. 6132032 and Japanese Patent No. 6107937 do not mention the temperature dependence of the temperature coefficient α of the temperature sensing portion.

As a result of intensive studies, the present inventors have found that by reducing the sheet resistance of each of the p-type anode region and the n-type cathode region (particularly, the sheet resistance of the n-type dopant layer) of the pn junction diode containing poly-silicon constituting the temperature sensing portion, the fluctuation range of the temperature coefficient α of the temperature sensing portion is reduced in the operating temperature range of the main semiconductor device element, and the temperature detection accuracy by the temperature sensing portion is improved. The present disclosure is made based on such findings. A problem to be solved in the present embodiment is to improve the temperature detection accuracy of the temperature sensing portion.

Hereinafter, embodiments of a silicon carbide semiconductor device and a method of manufacturing a silicon carbide semiconductor device according to the present disclosure will be described in detail with reference to the accompanying drawings. In the present specification and the accompanying drawings, layers and regions prefixed with n or p mean that majority carriers are electrons or holes, respectively. Further, + and − appended to n and p mean that the dopant concentration is higher and lower, respectively, than layers and regions without + and −. In the following description of the embodiments and the accompanying drawings, identical components are denoted by the same reference numerals, and redundant description thereof will be omitted.

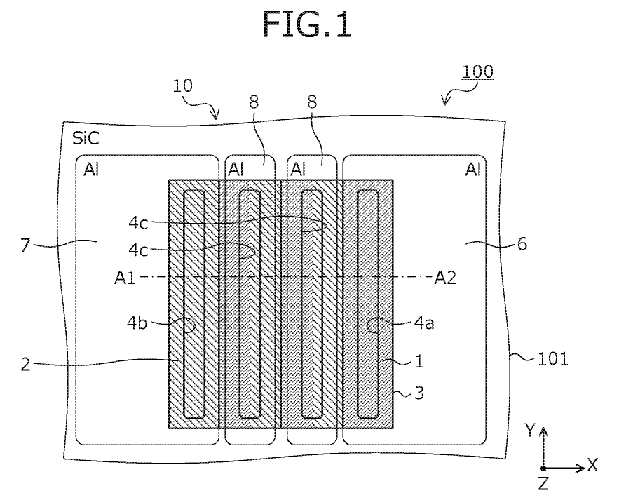

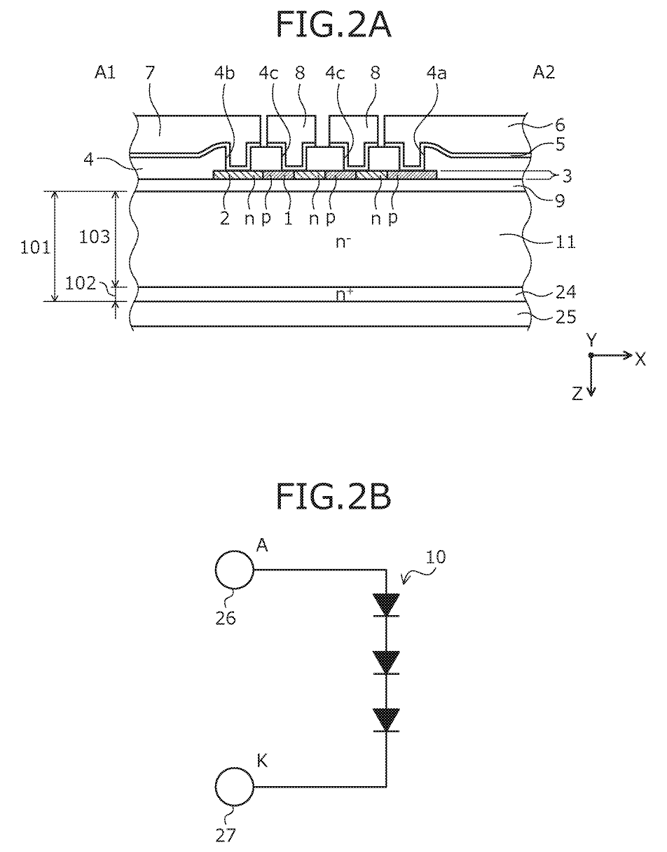

A silicon carbide semiconductor device according to a first embodiment that solves the above-described problem will be described below. FIG. 1 is a plan view depicting a layout of a temperature sensing portion of a silicon carbide semiconductor device according to a first embodiment as viewed from a front surface side of a semiconductor substrate. FIG. 2A is a cross-sectional view of a structure taken along a cutting line A1-A2 in FIG. 1. FIG. 2B is a circuit diagram depicting an equivalent circuit of the temperature sensing portion in FIG. 1. In FIGS. 1 and 2A, a p-type anode region 1 and an n-type cathode region 2 are indicated by different hatchings. The silicon carbide semiconductor device 100 according to the first embodiment depicted in FIGS. 1, 2A, and 2B includes a main semiconductor device element (not depicted) and a temperature sensing portion 10 for detecting the temperature of a main semiconductor device element in a semiconductor substrate (semiconductor chip) 101 in which silicon carbide (SiC) is used as a semiconductor material.

The semiconductor substrate 101 is a SiC substrate in which a SiC layer 103 of a predetermined conductivity type is grown by epitaxy on a front surface of a starting substrate 102 of a predetermined conductivity type and containing SiC. The semiconductor substrate 101 has a first main surface on the SiC layer 103 side as a front surface, and a second main surface on the starting substrate 102 side (a back surface of the starting substrate 102) as a back surface. When the main semiconductor device element is, for example, a vertical MOSFET, the starting substrate 102 is an n⁺-type drain region 24, and the n⁻-type SiC layer 103 serving as an n⁻-type drift region 11 is grown by epitaxy on the front surface of the n⁺-type starting substrate 102. A surface electrode on the back surface of the semiconductor substrate 101 is a drain electrode 25.

The temperature sensing portion 10 is configured by a lateral pn junction diode formed over an entire poly-silicon layer 3 provided on the front surface of the semiconductor substrate 101 via an interlayer insulating film 9. The temperature sensing portion 10 is electrically insulated from the semiconductor substrate 101 and other components formed in the semiconductor substrate 101 by interlayer insulating films 9 and 4. A field oxide film (not depicted) may be provided between the interlayer insulating film 9 and the semiconductor substrate 101 immediately below the temperature sensing portion 10. In the poly-silicon layer 3, a p-type anode region (first poly-silicon layer) 1 and an n-type cathode region (second poly-silicon layer) 2 are provided adjacent to each other in a first direction X parallel to the front surface of the semiconductor substrate 101. The p-type anode region 1 and the n-type cathode region 2 are selectively formed in the poly-silicon layer 3 by ion implantation.

The sheet resistance of the p-type anode region 1 (the p-type dopant layer in the poly-silicon layer 3) at 25 degrees C (room temperature) (hereinafter referred to as the sheet resistance at 25 degrees C) may be preferably not less than about 50 Ω/□ (ohms per square) but not more than about 170 Ω/□, which is the lower limit value that can be realized by adjusting the dose amount of the p-type dopant at the time of ion implantation for forming the p-type anode region 1. The sheet resistance of the n-type cathode region 2 (the n-type dopant layer in the poly-silicon layer 3) at 25 degrees C (hereinafter referred to as the sheet resistance at 25 degrees C) is not less than about 80Ω/□ but not more than about 400Ω/□, which is the lower limit value that can be realized by adjusting the dose amount of the n-type dopant at the time of ion implantation for forming the n-type cathode region 2.

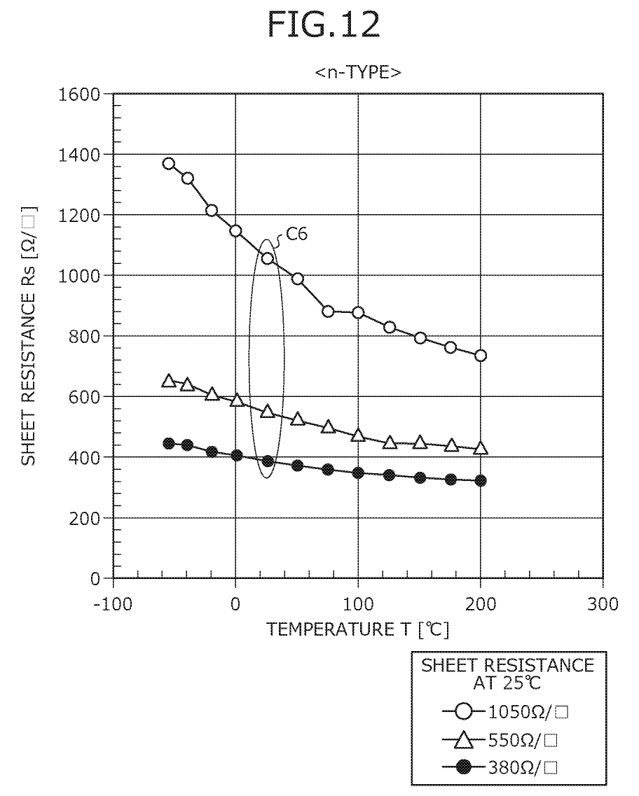

In both the p-type anode region 1 and the n-type cathode region 2, when the sheet resistance at 25 degrees C exceeds the upper limit value, the sheet resistance increases as the temperature T of the main semiconductor device element decreases. In particular, when the temperature T of the main semiconductor device element is a low temperature (a negative temperature of less than 0 degrees C), the range of fluctuation of the sheet resistance becomes large. On the other hand, in both the p-type anode region 1 and the n-type cathode region 2, by setting the sheet resistance at 25 degrees C to be not more than the upper limit value, the temperature dependence of the sheet resistance is reduced, and the range of fluctuation of the sheet resistance is reduced over the entire operating temperature range (for example, a range of about −50 degrees C to about 200 degrees C) of the main semiconductor device element (see FIGS. 11 and 12).

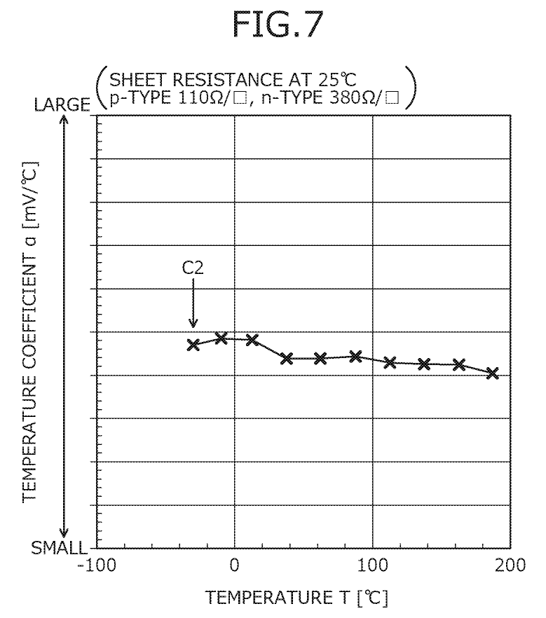

As a result, the fluctuation range of the temperature coefficient α [mV/degrees C] (hereinafter referred to as the temperature coefficient α of the temperature sensing portion) representing the rate of change of the difference in potential VF [mV] of the temperature sensing portion with respect to the change of the temperature T [degrees C] of the main semiconductor device element can be reduced over the entire operating temperature range of the main semiconductor device element (see FIG. 7). Since the dopant level of the p-type dopant (B or Sb) generated in the p-type anode region 1 is deeper than the dopant level of the n-type dopant (P or Sb) generated in the n-type cathode region 2, the temperature dependence of the sheet resistance of the p-type anode region 1 is smaller than the temperature dependence of the sheet resistance of the n-type cathode region 2. Therefore, at least the sheet resistance of the n-type cathode region 2 at 25 degrees C may be set within the above range. The difference between the sheet resistance at 25 degrees C of the p-type anode region 1 and the sheet resistance at 25 degrees C of the n-type cathode region 2 may be large.

As the p-type dopant used in the ion implantation for forming the p-type anode region 1, boron (B) or indium (In) having a dopant level shallower than that of B can be used. As an n-type dopant used for ion implantation for forming the n-type cathode region 2, phosphorus (P) or antimony (Sb) having a dopant level shallower than that of P can be used. That is, the p-type anode region 1 contains B or In as an acceptor. The n-type cathode region 2 contains P or Sb as a donor.

The temperature dependence of the difference in potential VF between the anode and the cathode (between an anode electrode 6 and a cathode electrode 7) of the temperature sensing portion 10 (voltage drop due to the forward current flowing through the temperature sensing portion 10) is obtained in advance, and the difference in potential VF of the temperature sensing portion 10 is measured during the operation of the main semiconductor device element. The temperature T of the main semiconductor device element (the surface temperature of the front surface of the semiconductor substrate 101) can be calculated based on the temperature dependence of the difference in potential VF of the temperature sensing portion 10. In order to make it possible to reliably measure the difference in potential VF of the temperature sensing portion 10, the temperature sensing portion 10 preferably has a structure in which multiple stages (in FIGS. 1, 2A, and 2B, 3 (three stages)) of lateral pn junction diodes are connected in series.

When the temperature sensing portion 10 has a structure in which multiple lateral pn junction diodes are connected in series, the p-type anode regions 1 and the n-type cathode regions 2 are arranged adjacent to each other in the poly-silicon layer 3 and repeatedly alternate each other by the same number of times as the number of pn junction diodes connected in series. As a result, adjacent pn junction diodes are directly connected to each other in the poly-silicon layer 3, and multiple pn junction diodes are connected in series. A difference in potential between the p-type anode region 1 (one end of the poly-silicon layer 3 in the first direction X) of the pn junction diode on the most upstream (previous stage) side and the n-type cathode region 2 (the other end of the poly-silicon layer 3 in the first direction X) of the pn junction diode on the most downstream (latter stage) side is a difference in potential VF between the anode and the cathode of the temperature sensing portion 10.

The p-type anode region 1 and the n-type cathode region 2 are arranged in a striped shape in a plan view (when viewed from the front surface side of the semiconductor substrate 101) and linearly extend by substantially the same length in a second direction Y that is parallel to the front surface of the semiconductor substrate 101 and orthogonal to the first direction X, for example. An interlayer insulating film 4 is provided on the poly-silicon layer 3 and the interlayer insulating film 9 and covers poly-silicon layer 3. The interlayer insulating film 4 is provided with contact holes 4a and 4b penetrating through the interlayer insulating film 4 in the depth direction Z and reaching the poly-silicon layer 3. The p-type anode region 1 and the n-type cathode region 2 are exposed in the contact holes 4a and 4b, respectively.

When the temperature sensing portion 10 has a structure in which multiple lateral pn junction diodes are connected in series, the interlayer insulating film 4 is further provided with the contact holes 4c the number of which is obtained by subtracting 1 from the number of pn junction diodes connected in series. The p-type anode region 1 of the most upstream pn junction diode is exposed in the contact hole 4a. The n-type cathode region 2 of the most downstream pn junction diode is exposed in the contact hole 4b. Junction portions between the pn junction diodes adjacent to each other (junction portions between the n-type cathode region 2 on the upstream side and the p-type anode region 1 on the downstream side) are exposed by different contact holes 4c. When the temperature sensing portion 10 detects the temperature by the reverse characteristic of the diode, the contact hole 4c may be omitted.

The anode electrode 6 is electrically connected to the p-type anode region 1 of the most upstream pn junction diode in the contact hole 4a. The anode electrode 6 may be in direct ohmic contact with the p-type anode region 1, or may be electrically connected to the p-type anode region 1 via a barrier metal (ohmic electrode) 5. The cathode electrode 7 is electrically connected to n-type cathode region 2 of the most downstream pn junction diode in contact hole 4b. The cathode electrode 7 may be in direct ohmic contact with the n-type cathode region 2, or may be electrically connected to the n-type cathode region 2 via the barrier metal 5.

Different connecting electrodes 8 are provided in the respective contact holes 4c. The connecting electrodes 8 connect adjacent pn junction diodes in series via the barrier metal 5 (or in direct contact) in the contact holes 4c. The anode electrode 6, the cathode electrode 7, and the connecting electrode 8 are, for example, an aluminum (Al) film or an Al alloy film. The anode electrode 6 and the cathode electrode 7 may also serve as electrode pads (an anode pad 26 and a cathode pad 27). The barrier metal 5 can be formed using a general metal material that forms an ohmic contact with the semiconductor substrate 101. The barrier metal 5 may have a function of preventing a mutual reaction between regions facing each other with the barrier metal 5 interposed therebetween.

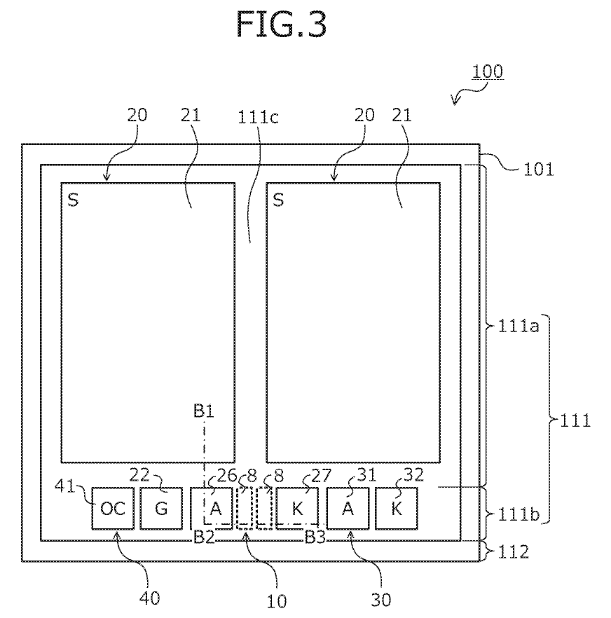

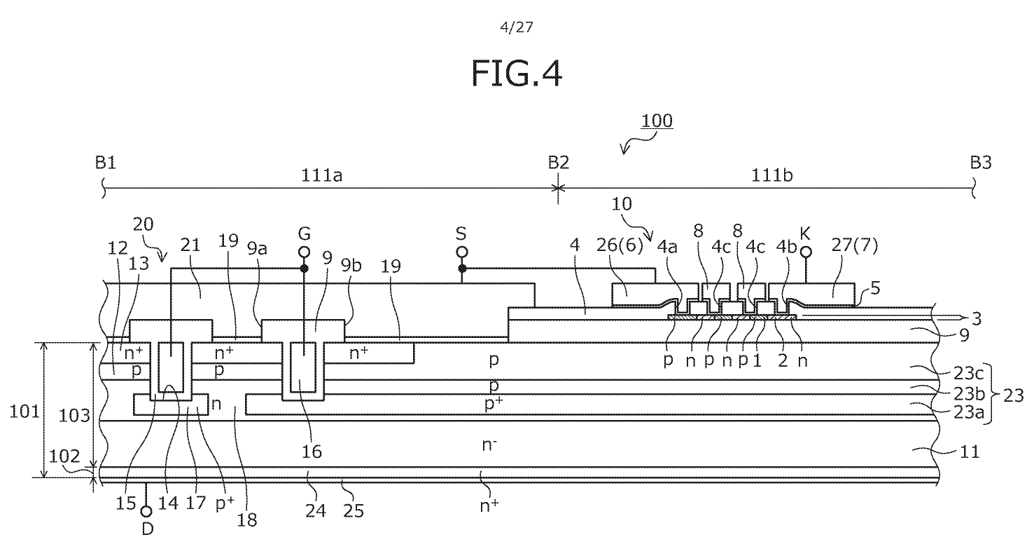

An application example of the above-described temperature sensing portion 10 will be described with reference to FIGS. 3 and 4. FIG. 3 is a plan view depicting a layout example of the silicon carbide semiconductor device according to the first embodiment as viewed from the front surface side of the semiconductor substrate. FIG. 3 depicts a layout example in which the entire semiconductor substrate 101 of FIG. 1 is viewed from the front surface side. FIG. 4 is a cross-sectional view depicting an example of a structure taken along a cutting line B1-B2-B3 in FIG. 3. Here, the MOSFET which is the main semiconductor device element 20, the temperature sensing portion 10, and an overvoltage protecting portion 30, a current sensing portion 40, and an arithmetic circuit portion (not depicted) which are other circuit portions are formed on the semiconductor substrate 101 depicted in FIG. 1.

As depicted in FIG. 3, the silicon carbide semiconductor device 100 according to the first embodiment includes the main semiconductor device element 20 and one or more circuit portions for protecting and controlling the main semiconductor device element 20, in the active region 111 of the same semiconductor substrate 101. The active region 111 has, for example, a substantially rectangular shape in a plan view and is provided substantially in the center (chip center) of the semiconductor substrate 101. In an operating region (hereinafter, referred to as a main operating region) 111a of the active region 111, multiple unit cells (functional units of a device) of the same structure connected in parallel to each other of the main semiconductor device element 20 are arranged. The main semiconductor device element 20 is a vertical MOSFET that performs a main operation of the silicon carbide semiconductor device 100.

The main operating region 111a is a region through which a main current of the main semiconductor device element 20 flows when the silicon carbide semiconductor device 100 is turned on. The main operating region 111a has, for example, a substantially rectangular shape in a plan view and occupies most of the surface area of the active region 111. A circuit portion for protecting and controlling the main semiconductor device element 20 is disposed in a main non-operating region 111b of the active region 111 excluding the main operating region 111a. The main non-operating region 111b is a region in which no unit cell of the main semiconductor device element 20 is disposed. The main non-operating region 111b has, for example, a substantially rectangular shape in a plan view and is disposed between the main operating region 111a and the edge termination region 112.

The edge termination region 112 is a region between the active region 111 and an end (chip end) of the semiconductor substrate 101, is adjacent to the active region 111, and surrounds the periphery of the active region 111 in a plan view. The edge termination region 112 has a function of relaxing an electric field of the front surface side of the semiconductor substrate 101 to maintain a breakdown voltage. In the edge termination region 112, for example, a general voltage withstanding structure (not depicted) such as a field limiting ring (FLR), a junction termination extension (JTE) structure, or a guard ring is disposed. The breakdown voltage is a voltage limit at which the silicon carbide semiconductor device does not malfunction or break down.

A source pad (electrode pad) 21 of the main semiconductor device element 20 is disposed on the front surface of the semiconductor substrate 101, in the main operating region 111a. The main semiconductor device element 20 has a larger current capability than the other circuit portions. Therefore, the source pad 21 of the main semiconductor device element 20 has substantially the same shape as that of the main operating region 111a in a plan view and covers substantially the entire surface of the main operating region 111a. Two source pads 21 having a substantially rectangular shape in a plan view may be disposed so as to cover substantially the entire surface of the main operating region 111a. In this case, in a portion 111c between the source pads 21 adjacent to each other as, for example, a main non-operating region, a gate finger (not depicted) or the like can be disposed.

As a circuit portion for protecting and controlling the main semiconductor device element 20, for example, the overvoltage protecting portion 30, the current sensing portion 40, the arithmetic circuit portion (not depicted), and the like may be disposed in addition to the temperature sensing portion 10 described above. A gate pad 22 of the main semiconductor device element 20, the electrode pads (the anode pad 26 and the cathode pad 27) of the temperature sensing portion 10, the electrode pads (an anode pad 31 and a cathode pad 32) of the overvoltage protecting portion 30, the electrode pad (hereinafter, referred to as an OC pad) 41 of the current sensing portion 40, and the electrode pad (not depicted) of the arithmetic circuit portion are disposed apart from each other on the front surface of the semiconductor substrate 101 in the main non-operating region 111b.

Each electrode pad has a surface area necessary for bonding of a predetermined metal wiring (not depicted) such as a terminal pin or a wire, and is exposed to different opening portions of a passivation film (not depicted) on the outermost surface of the front surface of the semiconductor substrate 101. In FIG. 3, the source pad 21, the gate pad 22, the anode pad 26, the cathode pad 27, the anode pad 31, the cathode pad 32, and the OC pad 41 are depicted in rectangular shapes denoted by S, G, A, K, A, K, and OC, respectively. A gate finger (not depicted, corresponding to the gate poly-silicon wiring layer 215 and the gate metal wiring layer 219 in FIG. 13) is provided in the edge termination region 112 and surrounds the periphery of the active region 111.

The temperature sensing portion 10 has a function of detecting the temperature of the main semiconductor device element 20 using the temperature characteristics of the diode as described above. The overvoltage protecting portion 30 is, for example, a diode that protects the main semiconductor device element 20 from an overvoltage (OV) such as a surge. The current sensing portion 40 has a function of detecting an overcurrent (OC) flowing through the main semiconductor device element 20. The arithmetic circuit portion has a function of controlling the temperature sensing portion 10, the overvoltage protecting portion 30, and the current sensing portion 40, and controlling the main semiconductor device element 20 based on output signals of the current sensing portion 40, the temperature sensing portion 10, and the overvoltage protecting portion 30.

A cross-sectional view of the structure of the main semiconductor device element 20 and the temperature sensing portion 10 in FIG. 3 will be described with reference to FIG. 4. The main semiconductor device element 20 is a vertical MOSFET including a trench gate structure on the front surface (first main surface on the SiC layer 103 side) side of the semiconductor substrate 101, in the main operating region 111a. As described above, the semiconductor substrate 101 is formed by growing, by epitaxy, the SiC layer 103 on the front surface of the n⁺-type starting substrate 102 containing SiC. The starting substrate 102 is the n⁺-type drain region 24 of the main semiconductor device element 20.

The trench gate structure includes a p-type base region 12, an n⁺-type source region 13, a p⁺⁺-type contact region (not depicted), trenches 14, gate insulating films 15, and gate electrodes 16. The p-type base region 12, the n⁺-type source region 13, and the p⁺⁺-type contact region are diffused regions formed in the SiC layer 103 by ion implantation. The p-type base region 12 is provided in an entire region between the front surface of the semiconductor substrate 101 and the n⁻-type drift region 11 in the main operating region 111a.

The n⁺-type source region 13 and the p⁺⁺-type contact region are each selectively provided between the front surface of the semiconductor substrate 101 and the p-type base region 12. In FIG. 4, the p⁺⁺-type contact region and the n⁺-type source region 13 are alternately provided in a longitudinal direction of the trenches 14. The n⁺-type source region 13 and the p⁺⁺-type contact region are in contact with the source electrode 19 on the front surface of the semiconductor substrate 101. The n⁺-type source region 13 faces the gate electrodes 16 via the gate insulating films 15 at sidewalls of the trenches 14. The p⁺⁺-type contact region may be omitted, and instead of the p⁺⁺-type contact region, the p-type base region 12 may be in contact with the source electrode 19 on the front surface of the semiconductor substrate 101.

The trenches 14 penetrate through the n⁺-type source region 13 and the p-type base region 12 in the depth direction from the front surface of the semiconductor substrate 101 and terminate in a CSL 18 described later or terminate in p⁺-type regions 17 described later via the CSL 18. The gate electrodes 16 are provided in the trenches 14 via the gate insulating films 15. The gate electrodes 16 are electrically connected to the gate pad 22 (not depicted) (see FIG. 3). The n⁺-type source region 13 may be omitted between the trenches 14 and the outer periphery of the main operating region 111a.

Between the p-type base region 12 and the n⁻-type drift region 11, the p⁺-type regions 17 and the CSL 18 are selectively provided closer to the n⁺-type drain region 24 than are the bottoms of the trenches 14. The p⁺-type regions 17 and the CSL 18 are diffused regions formed inside the SiC layer 103 by ion implantation.

The p⁺-type regions 17 are disposed apart from the p-type base region 12 in the depth direction and face the bottom surface of the trenches 14. The p⁺-type regions 17 are fixed to the potential of the source electrode 19 at a portion not depicted and have a function of relaxing the electric field applied to the bottoms of the trenches 14 by being depleted (or depleting the CSL 18) when the main semiconductor device element 20 is turned off. The p⁺-type regions 17 may surround the bottoms of the trenches 14 or may be apart from the bottoms of the trenches 14.

The CSL 18 is a so-called current spreading layer (CSL) that reduces spreading resistance of carriers. The CSL 18 is an n-type region having a dopant concentration higher than that of the n⁻-type drift region 11 and lower than that of the n⁺-type source region 13. The CSL 18 is in contact with the n⁻-type drift region 11, the p-type base region 12, and the p⁺-type regions 17, and reaches the trenches 14 between the p-type base region 12 and the p⁺-type regions 17.

The CSL 18 may reach a position deeper toward the n⁺-type drain region 24 than are the p⁺-type regions 17 and surround the p⁺-type regions 17. The CSL 18 may extend between a p-type region 23, which will be described later, of the main non-operating region 111b and the n⁻-type drift region 11. The n⁻-type drift region 11 may reach the p-type base region 12 and reach the trenches 14 between the p-type base region 12 and the p⁺-type regions 17 without providing the CSL 18.

A portion of the SiC layer 103 excluding the p-type base region 12, the n⁺-type source region 13, the p⁺⁺-type contact region, the p⁺-type regions 17, the CSL 18, the p-type region 23 of the main non-operating region 111b described later, and the voltage withstanding structure of the edge termination region 112 is the n⁻-type drift region 11. The SiC layer 103 may have a stacked structure in which an n⁻-type SiC layer serving as the n⁻-type drift region 11 and a p-type SiC layer serving as the p-type base region 12 are grown by epitaxy in this order.

In this case, the p⁺-type regions 17, the CSL 18, and the voltage withstanding structure are formed in the n⁻-type SiC layer of the SiC layer 103 by ion implantation, and a portion of the n⁻-type SiC layer excluding a diffused region formed by ion implantation is the n⁻-type drift region 11. The n⁺-type source region 13, the p⁺⁺-type contact region, and the p-type region 23 are formed in the p-type SiC layer of the SiC layer 103 by ion implantation, and a portion of the p-type SiC layer excluding a diffused region formed by ion implantation is the p-type base region 12.

The interlayer insulating film 9 is provided on substantially the entire front surface of the semiconductor substrate 101 and covers the gate electrodes 16. Contact holes 9a and 9b penetrating through the interlayer insulating film 9 in the depth direction are provided in the main operating region 111a. The n⁺-type source region 13 and the p⁺⁺-type contact region are exposed in the contact holes 9a and 9b. A contact (electrical contact portion) for extracting minority carriers in the n⁻-type drift region 11 to the source electrode 19 when the main semiconductor device element 20 is off is formed in the contact hole 9b.

The source electrode 19 is in ohmic contact with the front surface of the semiconductor substrate 101 in the contact holes 9a and 9b, and is electrically connected to the p-type base region 12, the n⁺-type source region 13, and the p⁺⁺-type contact region. The source electrode 19 can be formed using a general metal material that forms an ohmic contact with the semiconductor substrate 101. The source pad 21 is provided on the interlayer insulating film 9 and the source electrode 19 so as to be embedded in the contact holes 9a and 9b. The source pad 21 is, for example, an Al film or an Al alloy film.

A barrier metal (not depicted) may be provided between the source pad 21 and the interlayer insulating film 9 and the source electrode 19. The barrier metal has a function of preventing mutual reaction between regions facing each other with the barrier metal interposed therebetween. The interlayer insulating film 4 deposited at the time of forming the temperature sensing portion 10 may be interposed between the source pad 21 and the interlayer insulating film 9 (or between the barrier metal and the interlayer insulating film 9).

The drain electrode 25 is in ohmic contact with the entire back surface (second main surface on the starting substrate 102 side) of the semiconductor substrate 101 and is electrically connected to the n⁺-type drain region 24. The source pad 21, the drain pad (drain electrode 25), and the gate pad 22 of the main semiconductor device element 20 are electrically connected to the source terminal S, the drain terminal D, and the gate terminal G of the arithmetic circuit portion, respectively.

The temperature sensing portion 10 is provided on the interlayer insulating film 9 on the front surface of the semiconductor substrate 101, in the main non-operating region 111b. The temperature sensing portion 10 is similar to that depicted in FIG. 1, and is formed of a lateral pn junction diode including the p-type anode region 1 and the n-type cathode region 2 formed in the poly-silicon layer 3. The p-type region 23 may be provided between the front surface of the semiconductor substrate 101 and the n⁻-type drift region 11 directly below the temperature sensing portion 10.

The p-type region 23 is provided between the front surface of the semiconductor substrate 101 and the n⁻-type drift region 11 in the main non-operating region 111b and is coupled to the p-type base region 12 and the p⁺-type regions 17 of the main semiconductor device element 20. The p-type region 23 may include a p⁺-type regions 23a, a p-type region 23b, and a p-type region 23c adjacent to each other in this order in the depth direction from the n⁺-type drain region 24 side. The p⁺-type regions 23a is formed simultaneously with the p⁺-type regions 17, for example. The p-type regions 23b and 23c may be formed simultaneously with the p-type base region 12, for example.

In addition, the p-type region 23 may extend between the front surface of the semiconductor substrate 101 and the n⁻-type drift region 11 directly below the portion 111c between the mutually adjacent source pads 21 and the gate finger (not depicted) of the edge termination region 112. In addition, the p-type region 23 extends toward the chip end and is coupled to a p-type region (not depicted, corresponding to the p-type region 221 in FIG. 13) constituting the voltage withstanding structure of the edge termination region 112.

The configurations of the anode electrode 6, the cathode electrode 7, and the connecting electrode 8 are the same as those in FIG. 1. The anode electrode 6 also serves as, for example, the anode pad 26. The cathode electrode 7 also serves as the cathode pad 27. The anode pad 26 of the temperature sensing portion 10 is electrically connected to the source terminal S and the anode terminal A of the arithmetic circuit portion. The cathode pad 27 of the temperature sensing portion 10 is electrically connected to the cathode terminal K of the arithmetic circuit portion.

The operation of the silicon carbide semiconductor device 100 according to the first embodiment will be described. A positive voltage with respect to the source electrode 19 (source pad 21) of the main semiconductor device element 20 is applied to the drain electrode 25 (forward bias between the drain and the source), and the pn junctions between the p⁺-type regions 17, the p-type base region 12, the CSL 18, and the n⁻-type drift region 11 are reverse-biased. In this state, when the voltage applied to the gate electrodes 16 of the main semiconductor device element 20 is less than the gate threshold voltage, the main semiconductor device element 20 maintains the OFF state.

On the other hand, when a voltage equal to or higher than the gate threshold voltage is applied to the source electrode 19 of the main semiconductor device element 20 in a state where a forward bias is applied between the drain and the source, a channel (n-type inversion layer) is formed in portions of the p-type base region 12 of the main semiconductor device element 20 along the trenches 14. Thereby, a current flows from the n⁺-type drain region 24 of the main semiconductor device element 20 toward the n⁺-type source region 13 through the channel, and the main semiconductor device element 20 is turned on.

During the operation of the silicon carbide semiconductor device 100 (during a period when the drain-source of the main semiconductor device element 20 is forward-biased), a forward current is constantly supplied to the temperature sensing portion 10. In addition, during the operation of the main semiconductor device element 20, for example, the arithmetic circuit portion continuously monitors a difference in potential VF between the anode and the cathode of the temperature sensing portion 10 (a voltage drop due to a forward current flowing through the temperature sensing portion 10). Alternatively, the reverse current may be continuously supplied to the temperature sensing portion 10 at all times, and the voltage drop VR due to the reverse current flowing through the temperature sensing portion 10 may be continuously monitored.

As described above, since the fluctuation range of the temperature coefficient α of the temperature sensing portion 10 is small, the temperature coefficient α of the temperature sensing portion 10 is substantially constant regardless of the temperature T of the main semiconductor device element 20. Therefore, in the operating temperature range of the main semiconductor device element (for example, a range of about −50 degrees C to 200 degrees C), the relationship between the difference in the potential VF of the temperature sensing portion 10 (or the difference in the potential VR of the temperature sensing portion 10) and the temperature T of the main semiconductor device element 20 can be simply expressed as VF=αT (or VR=αT) using the temperature coefficient α.

Therefore, regardless of the temperature T of the main semiconductor device element 20, the temperature T of the main semiconductor device element 20 can be accurately detected using the simple relational expression between the difference in potential VF of the temperature sensing portion 10 and the temperature T of the main semiconductor device element 20. When the arithmetic circuit portion determines that a high-temperature region is generated in the main semiconductor device element 20, the arithmetic circuit portion stops the supply of the gate voltage to the main semiconductor device element 20 to stop the operation of the main semiconductor device element 20.

Accordingly, for example, even when a displacement current (corresponding to the displacement current Id in FIG. 13) flows toward the source electrode 19 through the p-type region constituting the voltage withstanding structure of the edge termination region 112 and the p-type region 23 of the main non-operating region 111b due to a temporal change (dV/dt) in the drain-source voltage of the main semiconductor device element 20, it is possible to avoid dielectric breakdown (corresponding to the dielectric breakdowns 232 and 234 in FIGS. 14 and 15) immediately below the gate finger, breakdown of the main semiconductor device element 20 due to a parasitic npn bipolar transistor operation using the displacement current Id as a base current, and the like.

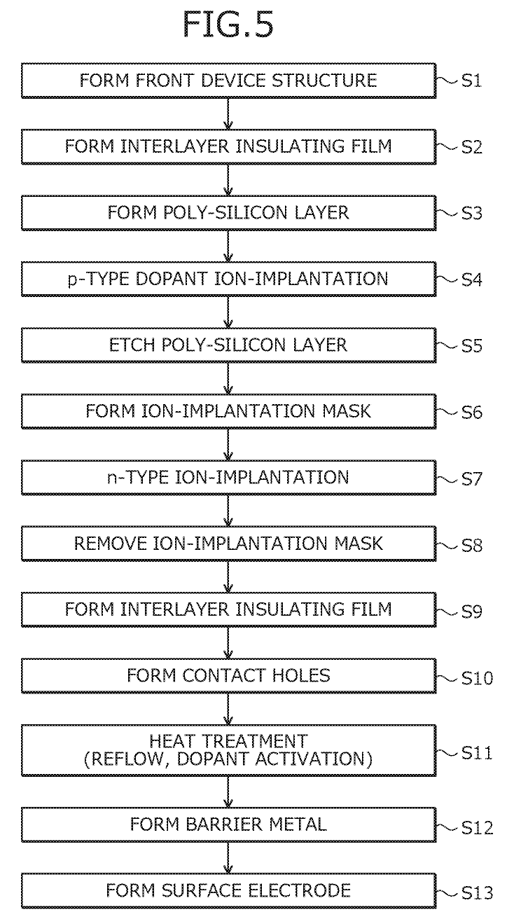

A method of manufacturing the silicon carbide semiconductor device 100 according to the first embodiment will be described with reference to FIGS. 3 and 4. FIG. 5 is a flowchart depicting an outline of the method of manufacturing the silicon carbide semiconductor device according to the first embodiment. First, the SiC layer 103 is grown by epitaxy on the front surface of the n⁺-type starting substrate (starting wafer) 102 containing SiC. Next, a front surface element structure is formed in a surface region of the SiC layer 103 (step S1: first process). The front surface element structure is a trench gate structure of the main semiconductor device element 20.

By the process at step S1, the semiconductor substrate (semiconductor wafer) 101 formed by stacking the SiC layer 103 on starting substrate 102 is fabricated. The SiC layer 103 may be grown by epitaxy in multiple stages according to the formation of each portion of the front surface element structure. Next, the interlayer insulating film 9 is formed on the entire front surface (surface of the SiC layer 103) of the semiconductor substrate 101 (step S2: second process). The interlayer insulating film 9 covers the trench gate structure of the main semiconductor device element 20 in the main operating region 111a and covers the front surface of the semiconductor substrate 101 in the main non-operating region 111b and the edge termination region 112. Before the process at step S2, a field oxide film (not depicted) may be formed on the front surface of the semiconductor substrate 101, in the main non-operating region 111b and the edge termination region 112.

Next, the non-doped poly-silicon layer 3 is formed on the interlayer insulating film 9 (step S3: second process). The thickness of the poly-silicon layer 3 is, for example, about 300 to 600 nm. Next, a p-type dopant is ion-implanted into the poly-silicon layer 3 to form the entire poly-silicon layer 3 into a p-type dopant layer to be the p-type anode region 1 (step S4: third process). The p-type dopant ion-implanted in the process at step S4 is B or In. At this time, the B dose amount (net charge amount) is, for example, at least about 7.0×10¹⁴/cm² but not more than 1.0×10¹⁶/cm². The In dose amount (net charge amount) is, for example, at least about 4.0×10¹⁴/cm² but not more than 7.0×10¹⁴/cm².

Next, the poly-silicon layer 3 is selectively removed by photolithography and etching to leave only a portion of the poly-silicon layer 3 to be the temperature sensing portion 10 (step S5). Next, an ion implantation mask is formed on the front surface of the semiconductor substrate 101 (step S6). The ion implantation mask has an opening that exposes a portion (a part of the poly-silicon layer 3) corresponding to a formation region of the n-type cathode region 2. Next, an n-type dopant is ion-implanted into the poly-silicon layer 3 using the ion implantation mask, and a part of the poly-silicon layer 3 is implanted back into an n-type, thereby forming an n-type dopant layer to be the n-type cathode region 2 in the poly-silicon layer 3 (step S7: fourth process).

The n-type dopant ion-implanted in the process at step S7 is P or Sb. At this time, the effective dose amount of P is, for example, about 1.0×10¹⁵/cm² or more but not more than 1.0×10¹⁶/cm². The effective dose amount of Sb is, for example, about 1.5×10¹⁵/cm² or more but not more than 2.5×10¹⁵/cm². The effective dose amount of the n-type dopant ion-implanted in the process at step S7 is a dose amount (net charge amount) obtained by subtracting the dose amount of the p-type dopant (B or In) ion-implanted in the process at step S4 from the dose amount of the n-type dopant (P or Sb) ion-implanted in the process at step S7.

It is sufficient that the sheet resistance at 25 degrees C of each of the p-type anode region 1 and the n-type cathode region 2 falls within the predetermined range in the heat treatment at step S11 described later, and the combination of the p-type dopant and the n-type dopant (any combination of B and P, B and Sb, In and P, or In and Sb) used in the processes at steps S4 and S7 can be appropriately selected. Next, the ion implantation mask is removed (step S8). By the steps up to this point, a lateral pn junction diode formed by the pn junction of the p-type anode region 1 and the n-type cathode region 2 and constituting the temperature sensing portion 10, is formed in the poly-silicon layer 3.

Next, the interlayer insulating film 4 is formed on the surfaces of the poly-silicon layer 3 and the interlayer insulating film 9 (step S9). Next, by photolithography and etching, the contact holes 9a and 9b are formed in the interlayer insulating film 9 in the main operating region 111a, and the contact holes 4a, 4b, and 4c are formed in the interlayer insulating film 4 in the main non-operating region 111b (step S10). The n⁺-type source region 13 and the p⁺⁺-type contact region (not depicted) are exposed in the contact holes 9a and 9b. The anode electrode 6, the cathode electrode 7, and the connecting electrode 8 are exposed in the contact holes 4a, 4b, and 4c, respectively.

Next, the surface of the interlayer insulating film is planarized (reflowed) by a heat treatment (step S11: fifth process). The heat treatment at step S11 also serves as a heat treatment for activating the p-type dopant and the n-type dopant in the poly-silicon layer 3, as a donor and an acceptor, respectively. By this heat treatment, the sheet resistance at 25 degrees C of each of the p-type anode region 1 and the n-type cathode region 2 is set within the predetermined range. The heat treatment temperature (activation temperature) at step S11 may be, for example, in a range of about 1050 degrees C to 1200 degrees C. When the activation temperature is less than the lower limit, a predetermined activation rate may not be obtained. When the activation temperature exceeds the upper limit, the front surface of the semiconductor substrate 101 may be oxidized, or Si crystals may excessively grow on the front surface of the semiconductor substrate 101.

Next, the barrier metal 5 is formed along the surface of the interlayer insulating film and the inner walls of contact holes 9a, 9b, 4a, 4b, and 4c (step S12). The surface of the interlayer insulating film in the processes at steps S11 and S12 is the exposed upper surface of the interlayer insulating film, and is the upper surface of the interlayer insulating film 9 in a portion where the interlayer insulating film 4 is not deposited, and is the upper surface of the interlayer insulating film 4 in a portion where the interlayer insulating film 4 is deposited. The inner walls of the contact holes 9a, 9b, 4a, 4b, and 4c are the side surfaces of the interlayer insulating films 9 and 4 and the surfaces exposed in the contact holes (the front surface of the semiconductor substrate 101 and the surface of the poly-silicon layer 3).

Next, a surface electrode (drain electrode 25) is formed on the back surface of the semiconductor substrate 101. An Al film (or an Al alloy film) serving as a surface electrode on the front surface of the semiconductor substrate 101 is formed on the barrier metal 5 so as to be embedded in the contact holes 9a, 9b, 4a, 4b, and 4c (step S13). The surface electrodes on the front surface of the semiconductor substrate 101 are the electrode pads and the connecting electrodes 8 on the front surface of the semiconductor substrate 101. Next, the Al film and the barrier metal 5 are patterned by photolithography and etching to form each electrode pad and the connecting electrode 8. Thereafter, the semiconductor wafer is cut (diced) into individual chips, thereby completing the silicon carbide semiconductor device 100 depicted in FIGS. 3 and 4.

As described above, according to the first embodiment, by setting the sheet resistance at 25 degrees C of the n-type cathode region of the pn junction diode formed inside the poly-silicon layer constituting the temperature sensing portion to 400 Ω/□ or less, the temperature dependence of the sheet resistance of the n-type cathode region can be reduced. Thus, the temperature dependence of the temperature coefficient of the temperature sensing portion can be reduced over the entire operating temperature range of the main semiconductor device element, and the temperature detection accuracy of the temperature sensing portion can be improved.

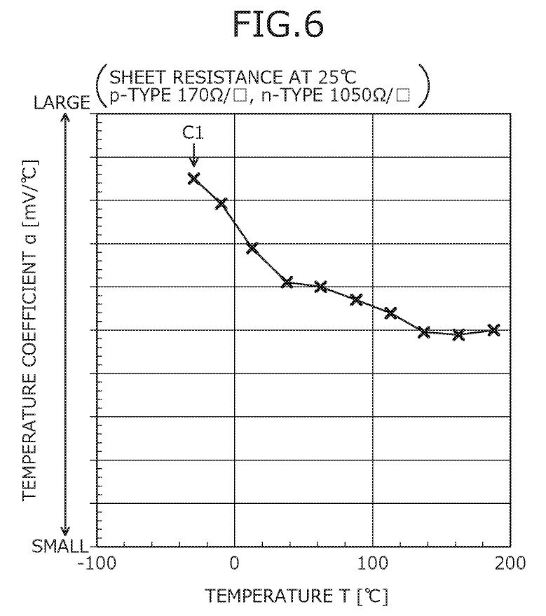

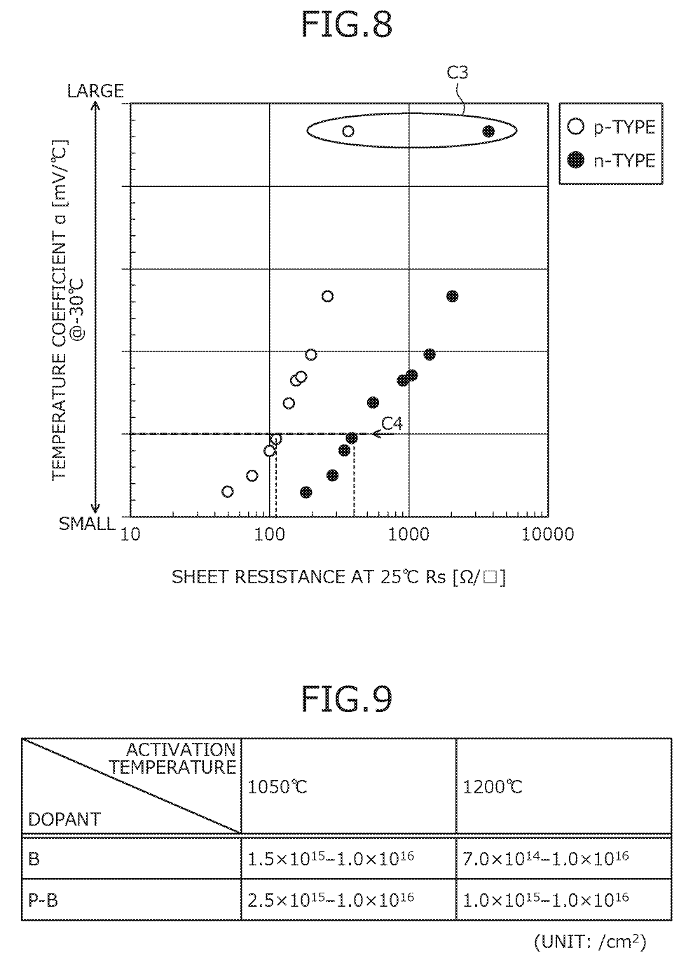

The temperature dependence of the temperature coefficient α of the temperature sensing portion 10 (the rate of change of the difference in the potential VF of the temperature sensing portion 10 with respect to the temperature change of the main semiconductor device element 20) was verified. FIGS. 6 and 7 are characteristic diagrams depicting the results of experimental verification of the temperature dependence of the temperature coefficient of the temperature sensing portion. The horizontal axes in FIGS. 6 and 7 represents the temperature T of the main semiconductor device element 20. The vertical axes of FIGS. 6 and 7 represent the temperature coefficient α of the temperature sensing portion 10. A larger numerical value (absolute value) of the temperature coefficient α (toward the upper side) indicates a larger temperature dependence of the temperature coefficient α, and a smaller numerical value (absolute value) of the temperature coefficient α (toward the lower side) indicates a smaller temperature dependence of the temperature coefficient α (the same applies to the vertical axis of FIG. 8).

FIGS. 6 and 7 depict the results of obtaining the relationship between the temperature coefficient α of the temperature sensing portion 10 and the temperature T of the main semiconductor device element 20 (the surface temperature of the front surface of the semiconductor substrate 101) for the temperature sensing portion 10 (hereinafter referred to as first and second verification examples). In the first verification example, the sheet resistances of the p-type anode region 1 and the n-type cathode region 2 at 25 degrees C were set to 170Ω/□ and 1050Ω/□, respectively. In the second verification example, the sheet resistances of the p-type anode region 1 and the n-type cathode region 2 at 25 degrees C were set to 110Ω/□ and 380Ω/□, respectively. The second verification example corresponds to the temperature sensing portion 10 of the silicon carbide semiconductor device 100 according to the first embodiment described above.

As depicted in FIG. 6, in the first verification example, it was confirmed that the temperature coefficient α of the temperature sensing portion 10 increases as the temperature T of the main semiconductor device element 20 decreases because the sheet resistance of the n-type cathode region 2 at 25 degrees C deviates from the range described in the first embodiment. The fluctuation range of the temperature coefficient α of the temperature sensing portion 10 is large particularly in a negative temperature range in which the temperature T of the main semiconductor device element 20 is 0 degrees C or less, and the fluctuation range of the temperature coefficient α of the temperature sensing portion 10 is largest at a measurement point C1 having the lowest temperature (=−30 degrees C) among the temperature measurement points of the main semiconductor device element 20.

On the other hand, as depicted in FIG. 7, in the second verification example, it was confirmed that the temperature coefficient α of the temperature sensing portion 10 varied minimally over the entire measurement range of the temperature T of the main semiconductor device element 20 because the sheet resistances of the p-type anode region 1 and the n-type cathode region 2 at 25 degrees C were within the ranges described in the first embodiment. As compared with the first verification example, the fluctuation range of the temperature coefficient α of the temperature sensing portion 10 was significantly reduced particularly in a vicinity C2 of the negative temperature range where the temperature T of the main semiconductor device element 20 was 0 degrees C or less.

FIG. 8 depicts the relationship between the sheet resistance of the temperature sensing portion 10 at 25 degrees C and the temperature coefficient α when the temperature T of the main semiconductor device element 20 is −30 degrees C. FIG. 8 is a characteristics diagram depicting a result of experimentally verifying a relationship between a temperature coefficient and a sheet resistance of the temperature sensing portion. The sheet resistances of the p-type anode region 1 and the n-type cathode region 2 at 25 degrees C were simultaneously changed to obtain the temperature coefficient α of the temperature sensing portion 10. Therefore, a combination (for example, two points surrounded by a circle C3) of the p-type anode region 1 and the n-type cathode region 2 (depicted as p-type and n-type) arranged side by side in FIG. 8 is one measurement value.

The p-type anode region 1 was formed by B ion implantation. The B dose amount was changed within a range including the B dose amount range described in the first embodiment (see step S4 in FIG. 5). The n-type cathode region 2 was formed by P ion implantation. The effective dose amount of P was changed within a range including the effective dose amount range of P described in the first embodiment (see step S7 in FIG. 5). In both the p-type anode region 1 and the n-type cathode region 2, the sheet resistance is reduced by increasing the dose amount.

As depicted in FIG. 8, it was confirmed that the temperature coefficient α of the temperature sensing portion 10 can be reduced by reducing the sheet resistance Rs of each of the p-type anode region 1 and the n-type cathode region 2 at 25 degrees C. For example, by setting the sheet resistances Rs of the p-type anode region 1 and the n-type cathode region 2 at 25 degrees C to 110Ω/□ and 400Ω/□, respectively, the temperature coefficient α of the temperature sensing portion 10 can be reduced to, for example, a predetermined value C4 that is generally practicable for in-vehicle use, as compared with the two points surrounded by the circle C3.

When the temperature coefficient α of the temperature sensing portion 10 is higher than the predetermined value C4, the temperature dependence of the temperature coefficient α of the temperature sensing portion 10 is as depicted in FIG. 6. When the temperature coefficient α of the temperature sensing portion 10 is equal to or less than the predetermined value C4, the temperature dependence of the temperature coefficient α of the temperature sensing portion 10 is as depicted in FIG. 7. That is, by reducing the sheet resistance Rs of each of the p-type anode region 1 and the n-type cathode region 2 at 25 degrees C, the fluctuation range of the temperature coefficient α of the temperature sensing portion 10 can be reduced over the entire measurement range of the temperature T of the main semiconductor device element 20.

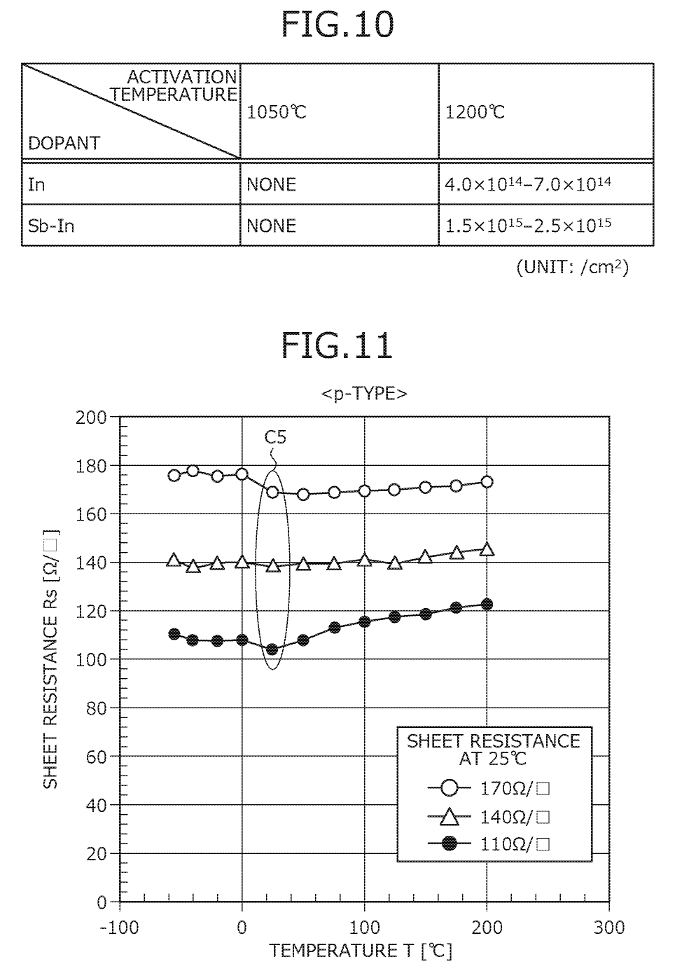

The relationship between the sheet resistance of the p-type anode region 1 at 25 degrees C and the dose of the p-type dopant (B or In) was verified. The preferable conditions of the sheet resistance of the n-type cathode region 2 at 25 degrees C and the effective dose of P (=P dose−B dose, depicted as dopant “P-B” in FIG. 9) were verified. The relationship between the sheet resistance of the n-type cathode region 2 at 25 degrees C and the effective dose amount of Sb (=Sb dose amount−In dose amount, depicted as dopant “Sb—In” in FIG. 10) was verified. FIGS. 9 and 10 are tables depicting the results of experimental verification of the relationship between the dose of the ion implantation at steps S4 and S7 in FIG. 5 and the activation temperature of the heat treatment at step S11.

As depicted in FIG. 9, when the p-type anode region 1 is formed by ion implantation of B, the B dose amount of the ion implantation at step S4 is set within a range of about 1.5×10¹⁵/cm² to 1.0×10¹⁶/cm², and the activation temperature of the heat treatment at step S11 is set at about 1050 degrees C. Alternatively, the B dose amount of the ion implantation at step S4 is set within a range of about 7.0×10¹⁴/cm² to 1.0×10¹⁶/cm², and the activation temperature of the heat treatment at step S11 is set at about 1200 degrees C. Thus, it was confirmed that the sheet resistance of the p-type anode region 1 at 25 degrees C can be set within the range described in the first embodiment.

As depicted in FIG. 9, when the n-type cathode region 2 is formed by ion implantation of P, the effective dose amount of P in the ion implantation at step S7 is set within a range of about 2.5×10¹⁵/cm² to 1.0×10¹⁶/cm², and the activation temperature of the heat treatment at step S11 is set at about 1050 degrees C. Alternatively, the effective P dose amount of the ion implantation at step S7 is set within a range of about 1.0×10¹⁵/cm² to 1.0×10¹⁶/cm², and the activation temperature of the heat treatment at step S11 is set to about 1200 degrees C. Thus, it was confirmed that the sheet resistance of the n-type cathode region 2 at 25 degrees C can be set within the range described in the first embodiment.

As depicted in FIG. 10, when the p-type anode region 1 is formed by ion implantation of In, the dose amount of In in the ion implantation at step S4 is set within a range of about 4.0×10¹⁴/cm² to 7.0×10¹⁴/cm², and the activation temperature of the heat treatment at step S11 is set at about 1200 degrees C. Thus, it was confirmed that the sheet resistance of the p-type anode region 1 at 25 degrees C could be set within the range described in the first embodiment.

As depicted in FIG. 10, when the n-type cathode region 2 is formed by ion implantation of Sb, the effective dose amount of Sb in the ion implantation at step S7 is set within a range of about 1.5×10¹⁵/cm² to 2.5×10¹⁵/cm², and the activation temperature of the heat treatment at step S11 is set at about 1200 degrees C. Thus, it was confirmed that the sheet resistance of the n-type cathode region 2 at 25 degrees C can be set within the range described in the first embodiment.

In a case where the p-type anode region 1 and the n-type cathode region 2 are formed by ion implantation of In and ion implantation of Sb, respectively, it has been confirmed that In and Sb are not activated when the activation temperature of the heat treatment at step S11 is as low as about 1050 degrees C (indicated as “none” in FIG. 10). For this reason, the activation temperature of the heat treatment at step S11 is preferably as high as possible but not more than 1200 degrees C.

Although the relationship between the sheet resistance of the n-type cathode region 2 at 25 degrees C and the effective dose amount of P with respect to the In dose amount (=P dose amount−In dose amount) and the relationship between the sheet resistance of the n-type cathode region 2 at 25 degrees C and the effective dose amount of Sb with respect to the B dose amount (=Sb dose amount−B dose amount) are not depicted, the sheet resistance of the n-type cathode region 2 at 25 degrees C can be set within the range described in the first embodiment by appropriately setting the dose amount and the activation rate of the n-type dopant (P or Sb) to be actually ion-implanted.

A preferable range of each sheet resistance Rs of the p-type anode region 1 and the n-type cathode region 2 at 25 degrees C was verified. FIG. 11 is a characteristics diagram depicting a result of experimentally verifying the temperature dependence of the sheet resistance of the p-type anode region of the temperature sensing portion. FIG. 12 is a characteristics diagram depicting a result of experimentally verifying the temperature dependence of the sheet resistance of the n-type cathode region of the temperature sensing portion. The horizontal axes in FIGS. 11 and 12 represent the temperature T of the main semiconductor device element 20. The vertical axes in FIGS. 11 and 12 represent the sheet resistances Rs of the p-type anode region 1 and the n-type cathode region 2 of the temperature sensing portion 10, respectively.

FIG. 11 depicts the results of experimental verification of the temperature dependence of the sheet resistance Rs of the p-type anode region 1 for three samples having different sheet resistances Rs of the p-type anode region 1 of the temperature sensing portion 10. In all three samples in FIG. 11, the p-type anode region 1 was formed by B ion implantation. In the three samples in FIG. 11, the B dose amount was adjusted so that the sheet resistance (portion surrounded by a circle C5) at 25 degrees C of the p-type anode region 1 was 110Ω/□, 140Ω/□, and 170Ω/□, respectively. The thickness of the temperature sensing portion 10 (the thickness of the poly-silicon layer 3) was set to 400 nm.

FIG. 12 depicts the results of experimental verification of the temperature dependence of the sheet resistance Rs of the n-type cathode region 2 for three samples having different sheet resistances Rs of the n-type cathode region 2 of the temperature sensing portion 10. In all three samples in FIG. 12, the n-type cathode region 2 was formed by ion implantation of P. In the three samples in FIG. 12, the P dose amount was adjusted so that the sheet resistance (portion surrounded by a circle C6) of the n-type cathode region 2 at 25 degrees C became 380Ω/□, 550Ω/□, and 1050Ω/□, respectively. The thickness of the temperature sensing portion 10 (the thickness of the poly-silicon layer 3) was set to 400 nm.

As depicted in FIG. 11, it was confirmed that the temperature dependence of the sheet resistance of the p-type anode region 1 of the temperature sensing portion can be reduced over the entire range of the temperature T of the main semiconductor device element 20 from −50 degrees C to about 200 degrees C by adjusting the B dose amount so that the sheet resistance of the p-type anode region 1 at 25 degrees C is 170 Ω/□ or less. Further, it was confirmed that when the p-type anode region 1 was formed with the upper limit value (1.0×10¹⁶/cm²: see FIG. 9) of the range of the B dose amount in the ion implantation, the sheet resistance of the p-type anode region 1 at 25 degrees C became 50 Ω/□.

As depicted in FIG. 12, it was confirmed that the temperature dependence of the sheet resistance of the n-type cathode region 2 of the temperature sensing portion can be reduced over the entire range of the temperature T of the main semiconductor device element 20 from −50 degrees C to about 200 degrees C by adjusting the effective dose amount of P such that the sheet resistance of the n-type cathode region 2 at 25 degrees C is 380 Ω/□ or less. Further, it was confirmed that when the n-type cathode region 2 was formed with the upper limit value (1.0×10¹⁶/cm²: see FIG. 9) of the range of the P dose amount of the ion implantation, the sheet resistance of the n-type cathode region 2 at 25 degrees C was 80 Ω/□.

As described above, by setting the sheet resistance of the n-type cathode region 2 at 25 degrees C to 400Ω/□, the temperature coefficient α of the temperature sensing portion 10 can be reduced to, for example, a predetermined value C4 that is generally practicable for in-vehicle use (see FIG. 8). Therefore, it is presumed that the temperature dependence of the sheet resistance of the n-type cathode region 2 of the temperature sensing portion can be reduced over the entire range of the temperature T of the main semiconductor device element 20 from −50 degrees C to about 200 degrees C by adjusting the effective dose amount of P so that the sheet resistance of the n-type cathode region 2 at 25 degrees C is 400 Ω/□ or less.

The temperature dependence of the sheet resistance of the p-type anode region 1 in the case where the p-type anode region 1 is formed by ion implantation of In is not depicted, but it is presumed that the same result as that in FIG. 11 is obtained by forming the p-type anode region 1 under the conditions depicted in FIG. 10. The temperature dependence of the sheet resistance of the n-type cathode region 2 when the n-type cathode region 2 is formed by Sb ion implantation is not depicted, but it is presumed that the same result as in FIG. 12 can be obtained by forming the n-type cathode region 2 under the conditions depicted in FIG. 10.

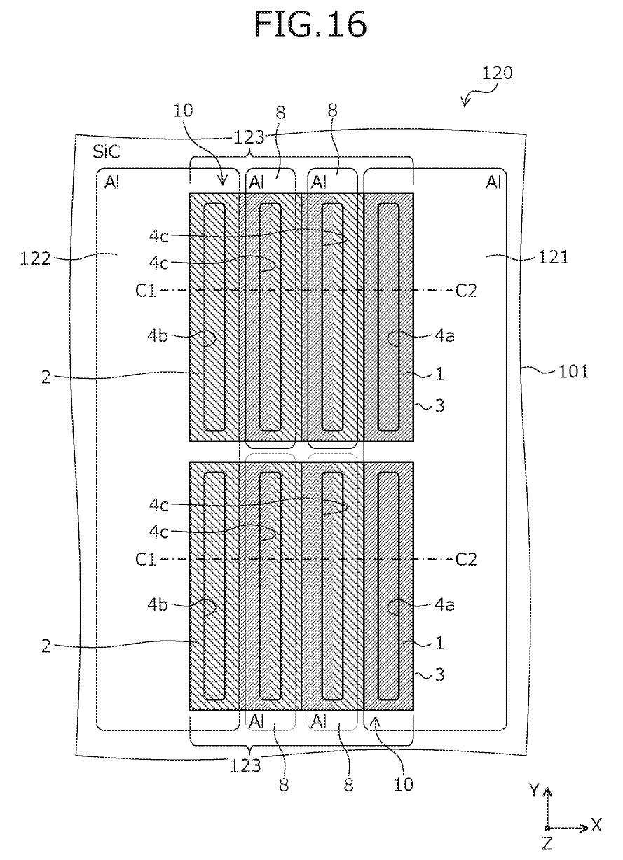

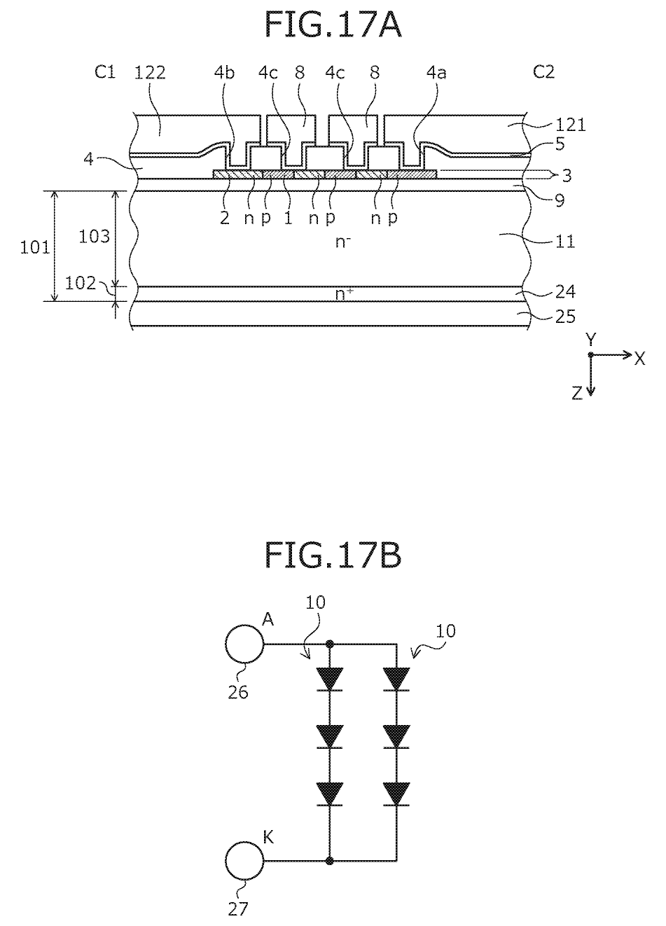

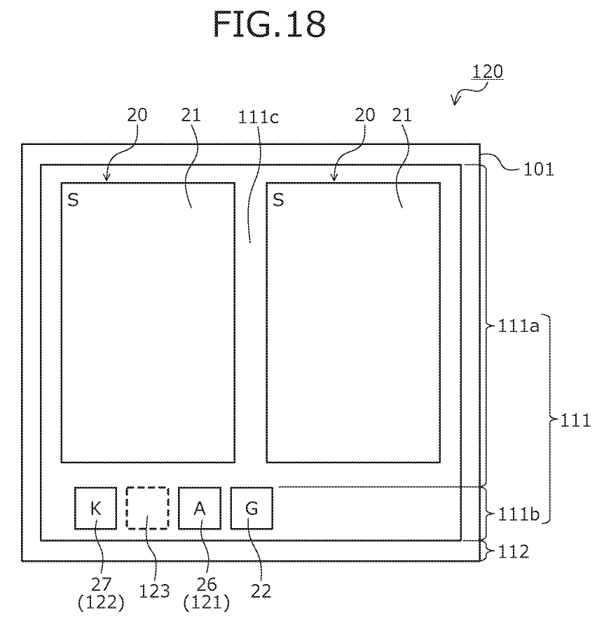

A silicon carbide semiconductor device according to a second embodiment will be described below. FIG. 16 is a plan view depicting a layout of the temperature sensing portion of the silicon carbide semiconductor device according to the second embodiment, as viewed from the front surface side of the semiconductor substrate. FIG. 17A is a cross-sectional view depicting a structure taken along a cutting line C1-C2 in FIG. 16. In FIGS. 16 and 17A, the p-type anode region 1 and the n-type cathode region 2 are indicated by different hatching. FIG. 17B is a circuit diagram depicting an equivalent circuit of the temperature sensing portion of FIG. 16. FIG. 18 is a plan view depicting a layout example of the silicon carbide semiconductor device according to the second embodiment, as viewed from the front surface side of the semiconductor substrate.

A silicon carbide semiconductor device 120 according to the second embodiment depicted in FIGS. 16,17A, 17B, and 18 is different from the silicon carbide semiconductor device 100 according to the first embodiment (see FIGS. 1, 2A, and 2B) in that multiple (here, two) temperature sensing portions (second diodes) 10 having the same structure and connected in parallel are provided on the interlayer insulating film 9 on the front surface of the semiconductor substrate 101. The silicon carbide semiconductor device 120 according to the second embodiment includes, on the semiconductor substrate 101, the main semiconductor device element 20 (see FIG. 4) having the same structure as that of the first embodiment, the temperature sensing portions 10 having the same structure as that of the first embodiment, and the anode electrode 121 and the cathode electrode 122 common to the temperature sensing portions 10.

In the second embodiment, as in the first embodiment, each temperature sensing portion 10 is formed of a lateral pn junction diode formed over an entire area of different poly-silicon layers 3. In FIG. 16, each temperature sensing portion 10 is formed by forming three stages of lateral pn junction diodes connected in series over the entire poly-silicon layer 3 as in the first embodiment. The multiple temperature sensing portions 10 are connected in parallel by electrically connecting the p-type anode regions 1 of the pn junction diodes on the most upstream side by one anode electrode 121 and electrically connecting the n-type cathode regions 2 of the pn junction diodes on the most downstream side by one cathode electrode 122.

Specifically, for example, in the second embodiment, the lateral pn junction diodes (the p-type anode region 1 and the n-type cathode region 2) constituting the respective temperature sensing portions 10 (the respective poly-silicon layers 3) extend in the same direction (here, the second direction Y) in a plan view. The temperature sensing portions 10 are spaced apart from each other in the second direction Y. The interlayer insulating film 4 is interposed between the temperature sensing portions 10 adjacent to each other. The temperature sensing portions 10 adjacent to each other in the second direction Y via the interlayer insulating film 4 are arranged such that the regions of the same conductivity type (the p-type anode regions 1 and the n-type cathode regions 2) of the pn junction diodes in the same stage connected in parallel face each other.

The interlayer insulating film 4 is provided with a set of the contact holes 4a to 4c at positions facing the poly-silicon layers 3 in the depth direction Z, respectively. The p-type anode region 1 of the most upstream pn junction diode of each temperature sensing portion 10 is exposed to a different contact hole 4a. The n-type cathode region 2 of the pn junction diode on the most downstream side of each temperature sensing portion 10 is exposed to different contact holes 4b. A contact hole 4c is provided for each junction portion between the pn junction diodes adjacent to each other in each temperature sensing portion 10, and the junction portions between the pn junction diodes are exposed to different contact holes 4c.

The contact holes 4a have, in a plan view, a shape of a straight line (line segment) extending apart from each other on the same straight line parallel to the second direction Y. The contact holes 4b have a linear (line segment) planar shape extending apart from each other on the same straight line parallel to the second direction Y. The contact holes 4c respectively exposing the junction portions of the pn junction diodes in the same stage connected in parallel have a linear (line segment) planar shape extending apart from each other on the same straight line parallel to the second direction Y. The contact holes 4a to 4c exposing the same poly-silicon layer 3 are arranged in stripes extending in the second direction Y adjacent to each other in the first direction X.

The anode electrode 121 extends linearly in the second direction Y and is embedded in all the contact holes 4a. The material of the anode electrode 121 and the configuration in the contact hole 4a are the same as those of the anode electrode 6 of the first embodiment. The cathode electrode 122 extends linearly in the second direction Y and is embedded in all the contact holes 4b. The material of the cathode electrode 122 and the configuration in the contact hole 4b are the same as those of the cathode electrode 7 of the first embodiment. Different connecting electrodes 8 are provided in the respective contact holes 4c. The material of the connecting electrode 8 and the configuration of the connecting electrode 8 in the contact hole 4c are the same as those in the first embodiment.

The anode electrode 121 electrically connects the p-type anode regions 1 of the most upstream pn junction diodes of all the temperature sensing portions 10 to each other. The cathode electrode 122 electrically connects the n-type cathode regions 2 of the most downstream pn junction diodes of all the temperature sensing portions 10 to each other. Multiple connecting electrodes 8 are arranged apart from each other in the same layout as the contact holes 4c. Each connecting electrode 8 connects adjacent pn junction diodes constituting the same temperature sensing portion 10 in series. In this manner, all the temperature sensing portions 10 are connected in parallel between the anode electrode 121 and the cathode electrode 122.

As in the first embodiment, all the temperature sensing portions 10 are disposed on the interlayer insulating film 9 on the front surface of the semiconductor substrate 101 in the main non-operating region 111b of the semiconductor substrate 101. Specifically, as depicted in FIG. 18, all the temperature sensing portions 10 connected in parallel are disposed in a region (hereinafter, referred to as a diode region) 123 between the anode pad 26 and the cathode pad 27 in the main non-operating region 111b. That is, in the diode region 123, all the connecting electrodes 8 (not depicted in FIG. 18, see FIG. 1 for the layout of the connecting electrodes 8 of the temperature sensing portions 10) and all the poly-silicon layers 3 are disposed. The diode region 123 is not provided with an electrode pad and is covered by a passivation film.

The anode electrode 121 is disposed outside the diode region 123 and faces the p-type anode region 1 of the pn junction diode on the most upstream side in the first direction X of all the temperature sensing portions 10. In addition, the anode electrode 121 extends in the diode region 123 so as to face the entire region of the p-type anode region 1 of the pn junction diode on the most upstream side of all the temperature sensing portions 10 in the depth direction Z. The anode pad 26 is disposed outside the diode region 123, faces the anode electrode 121 in the depth direction Z, and is electrically connected to the anode electrode 121. The anode pad 26 does not face the poly-silicon layer 3 in the depth direction Z.

The cathode electrode 122 is disposed outside the diode region 123 and faces the n-type cathode region 2 of the pn junction diode on the most downstream side in the first direction X of all the temperature sensing portions 10. In addition, the cathode electrode 122 extends in the diode region 123 so as to face the entire region of the n-type cathode region 2 of the pn junction diode on the most downstream side of all the temperature sensing portions 10 in the depth direction Z. The cathode pad 27 is disposed outside the diode region 123, faces the cathode electrode 122 in the depth direction Z, and is electrically connected to the cathode electrode 122. The cathode pad 27 does not face the poly-silicon layer 3 in the depth direction Z.

Portions of the anode electrode 121 and the cathode electrode 122 (portions exposed to the openings of the passivation film) may also serve as the anode pad 26 and the cathode pad 27, respectively. FIG. 18 depicts a case where the main semiconductor device element 20 and the temperature sensing portions 10 are formed in the semiconductor substrate 101 depicted in FIG. 16, but other circuit portions may be disposed in the main non-operating region 111b as in the first embodiment. The configuration of the main semiconductor device element 20 is the same as that of the first embodiment. In FIG. 18, the source pad 21, the gate pad 22, the anode pad 26, and the cathode pad 27 are depicted in rectangular shapes denoted by S, G, A, and K, respectively.

The gate pad 22 of the main semiconductor device element 20 may be disposed, for example, near the center of the main non-operating region 111b. Thus, the gate pad 22 is disposed at an equal distance from each of the portions immediately below the two source pads 21 (the two regions separated by the portion 111c between the source pads 21 adjacent to each other and in which the unit cells of the main semiconductor device element 20 are disposed), and the switching loss of the main semiconductor device element 20 can be suppressed. In this case, the temperature sensing portion 10 is disposed in a vicinity of a corner portion (vertex) of the semiconductor substrate 101, which has a substantially rectangular planar shape. However, since the semiconductor substrate 101 containing SiC easily conducts heat, the disposition of the temperature sensing portion 10 does not adversely affect the temperature detection accuracy of the temperature sensing portion 10.

As described above, according to the second embodiment, effects similar to those of the first embodiment can be obtained. Further, according to the second embodiment, the temperature sensing portion can be configured such that diode portions having the same function and containing poly-silicon are connected in parallel to each other, the diode portions being disposed apart from each other. Therefore, the degree of freedom in designing the temperature sensing portion is increased.

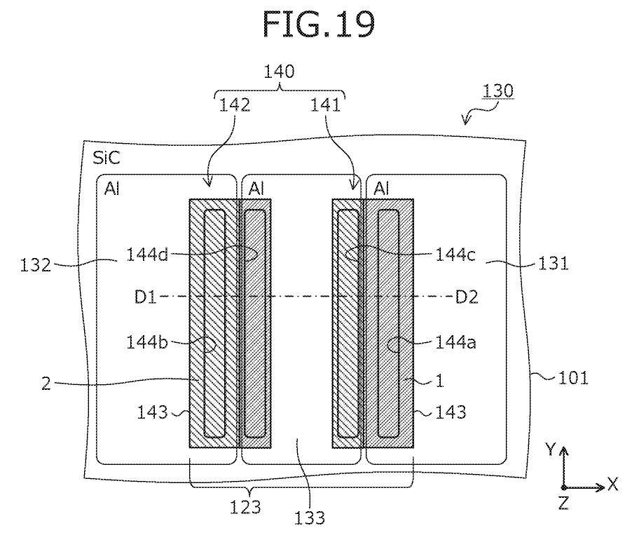

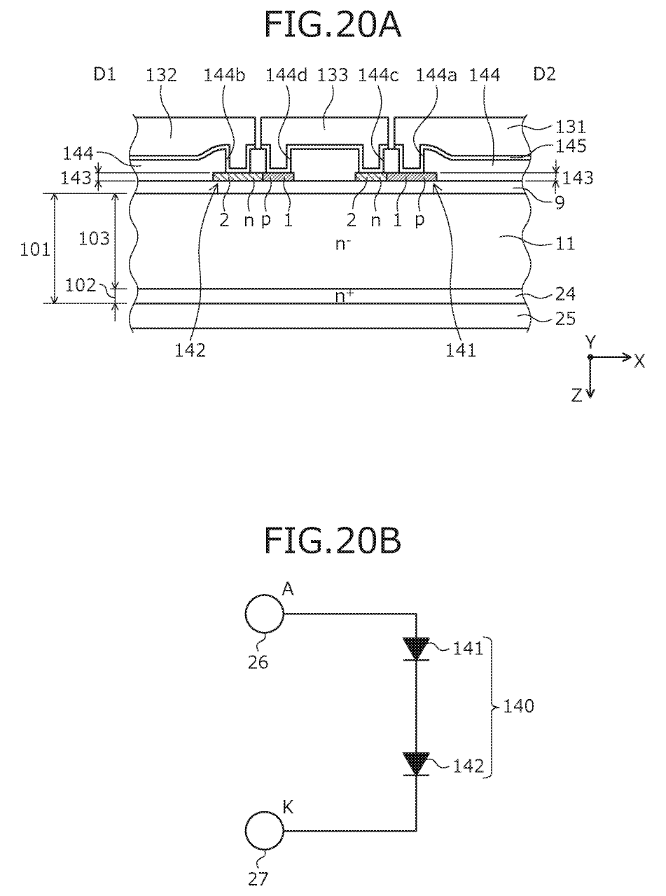

A silicon carbide semiconductor device according to a third embodiment will be described below. FIG. 19 is a plan view depicting a layout of the temperature sensing portion of the silicon carbide semiconductor device according to the third embodiment, as viewed from the front surface side of the semiconductor substrate. FIG. 20A is a cross-sectional view depicting a structure along a cutting line D1-D2 in FIG. 19. In FIGS. 19 and 20A, the p-type anode region 1 and the n-type cathode region 2 are indicated by different hatching. FIG. 20B is a circuit diagram depicting an equivalent circuit of the temperature sensing portion in FIG. 19. In a layout example of the silicon carbide semiconductor device 130 according to the third embodiment as viewed from the front surface side of the semiconductor substrate, reference numerals 120 to 122 in FIG. 18 are replaced with reference numerals 130 to 132, respectively.

The silicon carbide semiconductor device 130 according to the third embodiment depicted in FIGS. 19, 20A, and 20B is different from the silicon carbide semiconductor device 100 according to the first embodiment (see FIGS. 1, 2A, and 2B) in that two or more lateral pn junction diodes having the same structure constituting a temperature sensing portion 140 are connected in series only by the connecting electrode 133. In the third embodiment, the configuration of the main semiconductor device element 20 is the same as that of the first embodiment. The temperature sensing portion 140 includes two or more poly-silicon layers 143 having the same dimensions (width in the first direction X, length in the second direction Y, and thickness) provided apart from each other on the interlayer insulating film 9 on the front surface of the semiconductor substrate 101.

The two or more poly-silicon layers 143 are arranged apart from each other in the first direction X and linearly extend in the second direction Y by substantially the same length thereby forming a stripe pattern. The number of poly-silicon layers 143 is the same as the number of lateral pn junction diodes constituting the temperature sensing portion 140 (here, two: the most upstream pn junction diode 141 and the most downstream pn junction diode 142). Over the entire poly-silicon layer 143, in each poly-silicon layer 143, one lateral pn junction diode is formed by one set of the p-type anode region 1 and the n-type cathode region 2.

In each poly-silicon layer 143, the p-type anode region 1 and the n-type cathode region 2 are adjacent to each other in the first direction X and linearly extend in the second direction Y by substantially the same length. The configuration of the poly-silicon layer 143 is the same as that of the poly-silicon layer 3 of the first embodiment except that only one set of the p-type anode region 1 and the n-type cathode region 2 is formed in the poly-silicon layer 143. The configurations of the p-type anode region 1 and the n-type cathode region 2 are the same as those of the first embodiment except that the p-type anode region 1 and the n-type cathode region 2 are not directly connected to a pn junction diode formed by another p-type anode region 1 and another n-type cathode region 2 formed in another poly-silicon layer 143.

All the poly-silicon layers 143 are covered by an interlayer insulating film 144, and the interlayer insulating film 144 is interposed between the poly-silicon layers 143. The interlayer insulating film 144 is provided with contact holes 144a to 144d penetrating through the interlayer insulating film 144 in the depth direction Z and reaching the poly-silicon layer 143. The p-type anode region 1 and the n-type cathode region 2 of each poly-silicon layer 143 are exposed in different contact holes 144a to 144d.

The anode electrode 131 is electrically connected to the p-type anode region 1 of the most upstream pn junction diode 141 in the contact hole 144a. The arrangement, the material, and the configuration in the contact hole 144a of the anode electrode 131 are the same as the arrangement, the material, and the configuration in the contact hole 4a of the anode electrode 6 of the first embodiment. The configuration of the barrier metal 145 is the same as that of the barrier metal 5 of the first embodiment.

The cathode electrode 132 is electrically connected to the n-type cathode region 2 of the pn junction diode 142 on the most downstream side in the contact hole 144b. The arrangement and material of the cathode electrode 132 and the configuration in the contact hole 144b are the same as the arrangement and material of the cathode electrode 7 and the configuration in the contact hole 4b of the first embodiment.

The connecting electrode 133 is provided on the interlayer insulating film 144 between the anode electrode 131 and the cathode electrode 132 so as to be embedded in a pair of contact holes 144c and 144d adjacent to each other. The connecting electrode 133 is electrically connected to the n-type cathode region 2 of the pn junction diode 141 in the contact hole 144c, and is electrically connected to the p-type anode region 1 of the pn junction diode 142 on the most downstream side in the contact hole 144d. The material of the connecting electrode 133 and the configuration in the contact holes 144c and 144d are the same as the material of the connecting electrode 8 and the configuration in the contact hole 4c in the first embodiment.

When the temperature sensing portion 140 includes three or more poly-silicon layers 143, one or more poly-silicon layers 143 are disposed apart from each other between the poly-silicon layer 143 on the most upstream side electrically connected to the anode electrode 131 and the poly-silicon layer 143 on the most downstream side electrically connected to the cathode electrode 132. The number of sets of the contact holes 144c and 144d and the connecting electrodes 133 increases by one every time the number of poly-silicon layers 143 increases by one between the poly-silicon layer 143 on the most upstream side and the poly-silicon layer 143 on the most downstream side.

In this case, each connecting electrode 133 electrically connects the poly-silicon layers 143 adjacent to each other. Each connecting electrode 133 is disposed on the interlayer insulating film 144 so as to extend between the poly-silicon layers 143 adjacent to each other and is embedded in a pair of contact holes 144c and 144d adjacent to each other. Each connecting electrode 133 is electrically connected to the n-type cathode region 2 of the pn junction diode on the upstream side in the contact hole 144c and is electrically connected to the p-type anode region 1 of the pn junction diode on the downstream side in the contact hole 144d.

The second embodiment may be applied to the silicon carbide semiconductor device 130 according to the third embodiment, and multiple temperature sensing portions 140 connected in parallel and having the same structure may be disposed.

As described above, according to the third embodiment, effects similar to those of the first embodiment can be obtained. Further, according to the third embodiment, the pn junction diodes containing poly-silicon and disposed apart from each other are connected in series only by the connecting electrode, so that the degree of freedom of the layout of the temperature sensing portion is increased, for example, the interval between the pn junction diodes connected in series can be physically widened.

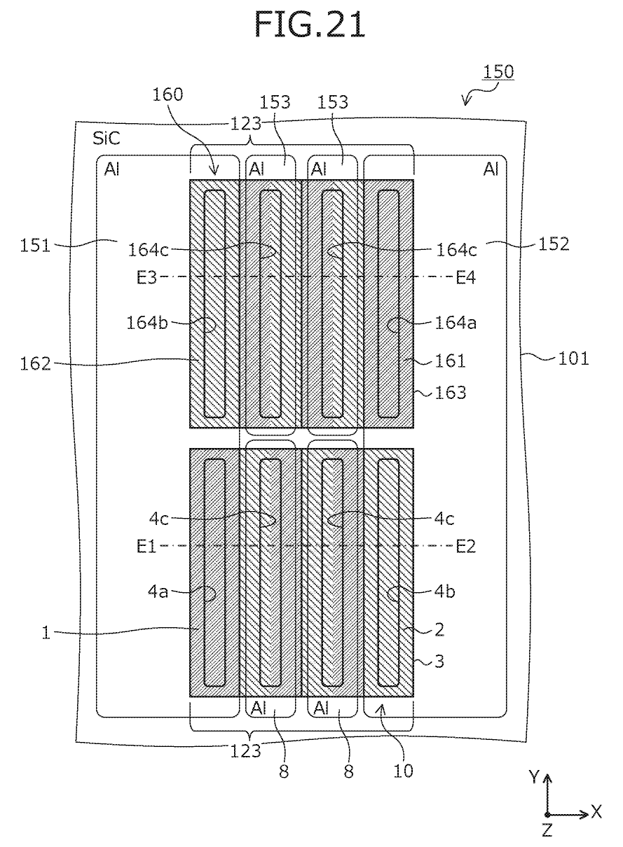

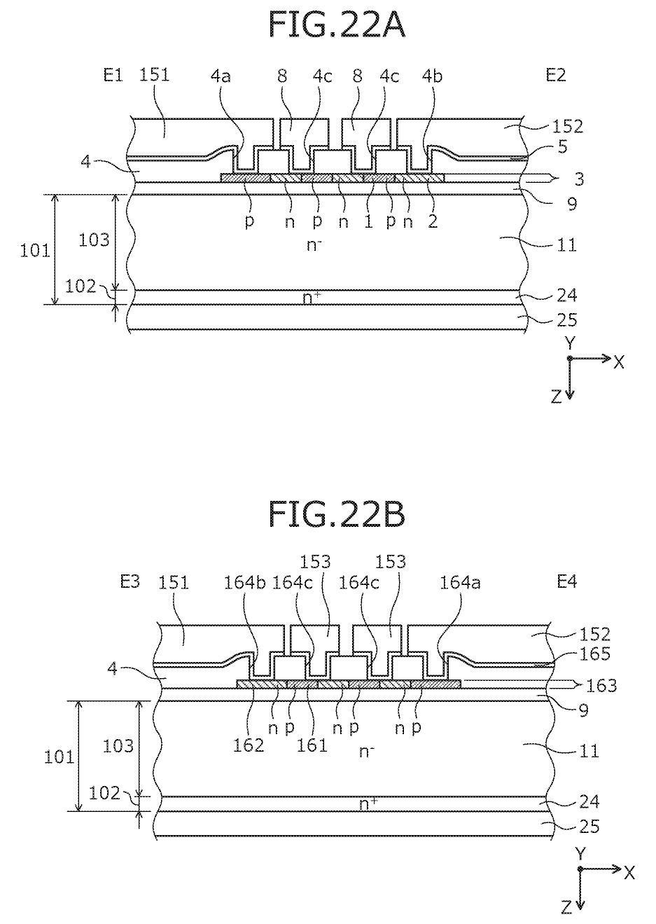

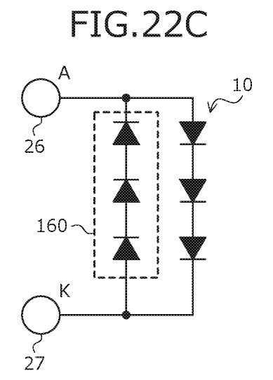

A silicon carbide semiconductor device according to a fourth embodiment will be described below. FIG. 21 is a plan view depicting a layout of the temperature sensing portion of the silicon carbide semiconductor device according to the fourth embodiment, as viewed from the front surface side of the semiconductor substrate. FIGS. 22A and 22B are cross-sectional views depicting a structure taken along cutting line E1-E2 and cutting line E3-E4 in FIG. 21, respectively. In FIGS. 21, 22A, and 22B, the p-type anode regions 1, 161 and the n-type cathode regions 2, 162 are indicated by different hatching. FIG. 22C is a circuit diagram depicting an equivalent circuit of the temperature sensing portion of FIG. 21.

A silicon carbide semiconductor device 150 according to the fourth embodiment depicted in FIGS. 21 and 22A to 22C is obtained by adding a protective diode (first diode) 160 to the silicon carbide semiconductor device 100 according to the first embodiment (see FIGS. 1, 2A, and 2B). The protective diode 160 is a pn junction diode connected in antiparallel to the temperature sensing portion 10, and has a function of protecting the silicon carbide semiconductor device 150 by absorbing a high voltage (for example, about 2 kV) exceeding an electro static discharge (ESD) tolerance or a large current generated by the high voltage by using Zener breakdown of the protective diode 160. The protective diode 160 corresponds to, for example, the overvoltage protecting portion 30 of the first embodiment.

The anode of the protective diode 160 is connected to the lowest potential point (here, the cathode terminal K of the temperature sensing portion 10) of the silicon carbide semiconductor device 150 (FIG. 22C). During normal operation of the temperature sensing portion 10, the protective diode 160 is in a reverse bias state, and the protective diode 160 does not conduct unless the potential of the anode terminal A of the temperature sensing portion 10 exceeds the potential of the lowest potential point of the silicon carbide semiconductor device 150. On the other hand, the protective diode 160 conducts when a transient voltage exceeding the Zener voltage of the protective diode 160 is applied and protects the silicon carbide semiconductor device 150 by leading out a current (caused by the transient voltage) to the outside of the silicon carbide semiconductor device 150.

In the fourth embodiment, the configurations of the main semiconductor device element 20 (see FIG. 4) and the temperature sensing portion 10 (FIGS. 21 and 22A) are similar to those of the first embodiment. The temperature sensing portion 10 depicted in FIGS. 21 and 22A is in a state in which the positions of the upstream side (anode electrode 151 side) and the downstream side (cathode electrode 152 side) of the temperature sensing portion 10 in FIGS. 1 and 2A are horizontally reversed. The layout example of the silicon carbide semiconductor device 150 according to the fourth embodiment when viewed from the front surface side of the semiconductor substrate body is obtained by replacing the positions of the anode pad 26 and the cathode pad 27 in FIG. 18 and replacing the reference numerals 120 to 122 with reference numerals 150 to 152, respectively.

The protective diode 160 is a lateral pn junction diode formed over the entire poly-silicon layer 163. The poly-silicon layer 163 constituting the protective diode 160 is disposed on the interlayer insulating film 9 on the front surface of the semiconductor substrate 101 so as to be separated from the poly-silicon layer 3 constituting the temperature sensing portion 10, and faces the poly-silicon layer 3 in the second direction Y. The poly-silicon layer 163 has, in a plan view, substantially the same shape as the poly-silicon layer 3 and has substantially the same dimensions (width and height in the first and second directions X and Y) as the poly-silicon layer 3. In the poly-silicon layer 163, a p-type anode region 161 and an n-type cathode region 162 are provided adjacent to each other. The p-type anode region 161 and the n-type cathode region 162 are adjacent to each other in the first direction X and linearly extend in the second direction Y by substantially the same length.

The p-type anode region 161 and the n-type cathode region 162 are selectively formed in the poly-silicon layer 163 by ion implantation. The dopant concentrations of the p-type anode region 161 and the n-type cathode region 162 are substantially the same as the dopant concentrations of the p-type anode region 1 and the n-type cathode region 2 in the poly-silicon layer 3 constituting the temperature sensing portion 10, respectively. Therefore, in the method of manufacturing the silicon carbide semiconductor device 100 according to the first embodiment, by appropriately changing the patterns of the ion implantation masks for forming the p-type anode region 1 and the n-type cathode region 2, the p-type anode region 161 and the p-type anode region 1 can be simultaneously formed, and the n-type cathode region 162 and the n-type cathode region 2 can be simultaneously formed.

The number (here, three) of pn junction diodes formed inside the poly-silicon layer 163 and connected in series to each other to constitute the protective diode 160 may be the same as the number of pn junction diodes formed inside the poly-silicon layer 3 constituting the temperature sensing portion 10 and connected in series to each other to constitute the temperature sensing portion 10. The configuration of the poly-silicon layer 163 is the same as that of the poly-silicon layer 3 except that the arrangement of the p-type anode region 161 and the n-type cathode region 162 in the first direction X is opposite to the arrangement of the p-type anode region 1 and the n-type cathode region 2 in the first direction X in the poly-silicon layer 3.

The p-type anode regions 161 in the poly-silicon layer 163 face different n-type cathode regions 2 in the poly-silicon layer 3 in the second direction Y, respectively. The p-type anode region 161 in the poly-silicon layer 163 and the n-type cathode region 2 in the poly-silicon layer 3 have linear (line segment) shapes in a plan view, extending apart from each other on the same straight line parallel to the second direction Y. The p-type anode region 161 of the most upstream pn junction diode of the protective diode 160 faces the n-type cathode region 2 of the most downstream pn junction diode of the temperature sensing portion 10 in the second direction Y.

Therefore, the n-type cathode regions 162 in the poly-silicon layer 163 face different p-type anode regions 1 in the poly-silicon layer 3 in the second direction Y, respectively. The n-type cathode region 162 in the poly-silicon layer 163 and the p-type anode region 1 in the poly-silicon layer 3 have linear (line segment) shapes in a plan view, extending apart from each other on the same straight line parallel to the second direction Y. The n-type cathode region 162 of the most downstream pn junction diode of the protective diode 160 faces the p-type anode region 1 of the most upstream pn junction diode of the temperature sensing portion 10.

The poly-silicon layers 163 and 3 are covered by the interlayer insulating film 4, and the interlayer insulating film 4 is interposed between the poly-silicon layer 163 and the poly-silicon layer 3. The poly-silicon layers 163 and 3 are electrically insulated from the semiconductor substrate 101 and other elements formed on the semiconductor substrate 101 by the interlayer insulating films 9 and 4. A field oxide film (not depicted) may be provided between the interlayer insulating film 9 and the semiconductor substrate 101 immediately below the poly-silicon layers 163 and 3.

The interlayer insulating film 4 is provided with contact holes 4a to 4c at positions facing the poly-silicon layer 3 in the depth direction Z, as in the first embodiment. The interlayer insulating film 4 is provided with contact holes 164a to 164c penetrating through the interlayer insulating film 4 in the depth direction Z and reaching the poly-silicon layer 163. The configurations of the contact holes 164a to 164c are the same as those of the contact holes 4a to 4c, respectively, except that the contact holes 164a to 164c are provided at positions facing the protective diode 160 (poly-silicon layer 163) in the depth direction Z.

The p-type anode region 161 of the most upstream pn junction diode of the protective diode 160 is exposed in the contact hole 164a. The n-type cathode region 162 of the most downstream pn junction diode of the protective diode 160 is exposed in the contact hole 164b. Junction portions between the pn junction diodes adjacent to each other in the protective diode 160 (junction portions between the n-type cathode region 162 on the upstream side and the p-type anode region 161 on the downstream side) are exposed by different contact holes 164c.

The contact hole 164a and the contact hole 4b have a linear (line segment) shape in a plan view, extending apart from each other on the same straight line parallel to the second direction Y. The contact hole 164b and the contact hole 4a have a linear (line segment) shape in a plan view, extending apart from each other on the same straight line parallel to the second direction Y. The contact holes 164c face different contact holes 4c in the second direction Y, respectively. The contact hole 164c and the contact hole 4c have a linear (line segment) shape in a plan view, extending apart from each other on the same straight line parallel to the second direction Y.

The anode electrode 151 and the cathode electrode 152 of the temperature sensing portion 10 are provided on the interlayer insulating film 4 so as to face the upstream side and the downstream side of the poly-silicon layer 3 in the depth direction Z, respectively. The anode electrode 151 and the cathode electrode 152 linearly extend toward the protective diode 160 (here, the second direction Y) and face the downstream side and the upstream side of the poly-silicon layer 163 in the depth direction Z, respectively. The anode electrode 151 and the cathode electrode 152 serve as a cathode electrode and an anode electrode of the protective diode 160, respectively. The anode electrode 151 and the cathode electrode 152 may also serve as the anode pad 26 and the cathode pad 27, respectively.

The anode electrode 151 is embedded in the contact hole 4a to be electrically connected to the p-type anode region 1 of the pn junction diode on the most upstream side of the temperature sensing portion 10, and is embedded in the contact hole 164b to be electrically connected to the n-type cathode region 162 of the pn junction diode on the most downstream side of the protective diode 160 (pn junction diode closest to the anode terminal A). The configuration of a portion of the anode electrode 151 facing the poly-silicon layer 3 in the depth direction Z, the material of the anode electrode 151, and the configuration in the contact hole 4a are the same as those of the anode electrode 6 of the first embodiment. The configuration of the anode electrode 151 in the contact hole 164b and the configuration of the anode electrode 151 in the contact hole 4a may be the same.

The cathode electrode 152 is embedded in the contact hole 4b to be electrically connected to the n-type cathode region 2 of the pn junction diode on the most downstream side of the temperature sensing portion 10, and is embedded in the contact hole 164a to be electrically connected to the p-type anode region 161 of the pn junction diode on the most upstream side of the protective diode 160 (the pn junction diode farthest from the anode terminal A). The configuration of a portion of the cathode electrode 152 facing the poly-silicon layer 3 in the depth direction Z, the material of the cathode electrode 152, and the configuration in the contact hole 4b are the same as those of the cathode electrode 7 of the first embodiment. The configuration of the cathode electrode 152 in the contact hole 164a and the configuration of the cathode electrode 152 in the contact hole 4b are preferably the same.

Different connecting electrodes 8 are provided in the respective contact holes 4c. The configuration of the connecting electrode 8 is the same as in the first and second embodiments. Different connecting electrodes 153 are provided in the respective contact holes 164c. The connecting electrode 153 and the poly-silicon layer 163 are disposed in the diode region 123 apart from the connecting electrode 8 and the poly-silicon layer 3. The connecting electrode 153 connects the adjacent pn junction diodes of the protective diode 160 in series via the barrier metal (or in direct contact) in the contact hole 164c. The material of the connecting electrode 153 and the configuration in the contact hole 164c are preferably the same as the material of the connecting electrode 8 and the configuration in the contact hole 4c.

As described, the diode portion formed in one of the poly-silicon layers arranged apart from each other on the interlayer insulating film 9 serves as the protective diode 160. The diode portion serving as the protective diode 160 can be connected in antiparallel to the diode portion formed in the remaining poly-silicon layer serving as the temperature sensing portion 10 by the anode electrode 151 and the cathode electrode 152. In FIG. 22C, the protective diode 160 is inserted (connected) at a position closer to the anode terminal A and the cathode terminal K than the temperature sensing portion 10, but may be inserted at a position farther from the anode terminal A and the cathode terminal K than the temperature sensing portion 10.

The p-type anode region 161 and the n-type cathode region 162 may be formed under the same conditions as the p-type anode region 1 and the n-type cathode region 2, respectively. This makes it possible to select, after completion of the silicon carbide semiconductor device 150, which of multiple (here, two) diode portions (poly-silicon layers 3 and 163) disposed apart from each other on the interlayer insulating film 9 on the front surface of the semiconductor substrate 101 is to be used as the protective diode 160.

The number of stages of the pn junction diodes formed in the poly-silicon layers 3 and 163 may be different from each other. The temperature sensing portion 10 and the protective diode 160 may be electrically insulated from the main semiconductor device element 20. Since the temperature sensing portion 10 and the protective diode 160 are electrically insulated from the main semiconductor device element 20, the temperature sensing portion 10 and the protective diode 160 are less likely to be adversely affected by the operation of the main semiconductor device element 20 (for example, an operation that may cause breakdown or deterioration, such as breakdown).

In the fourth embodiment, the temperature T of the main semiconductor device element 20 is detected using the voltage drop VF due to the forward current flowing through the temperature sensing portion 10 during the operation of the silicon carbide semiconductor device 150 (during the period in which the drain-source of the main semiconductor device element 20 is forward-biased). Since the protective diode 160 is attached to the silicon carbide semiconductor device 150, the temperature T of the main semiconductor device element 20 cannot be detected using the voltage drop VR due to the reverse current flowing through the temperature sensing portion 10.

The second embodiment (see FIG. 16) may be applied to the silicon carbide semiconductor device 150 according to the fourth embodiment to dispose multiple temperature sensing portions 10 connected in parallel and having the same structure or to dispose multiple protective diodes 160 connected in parallel and having the same structure. Further, the third embodiment (see FIG. 21) may be applied to the silicon carbide semiconductor device 150 according to the fourth embodiment, the temperature sensing portion 10 may be replaced with the temperature sensing portion 140 of the third embodiment, and the protective diode 160 may be replaced with the same configuration as the temperature sensing portion 140 of the third embodiment.

As described above, according to the fourth embodiment, effects similar to those of the first to third embodiments can be obtained. According to the fourth embodiment, diode portions (temperature sensing portion, protective diode) having different functions by poly-silicon can be formed by poly-silicon layers (p-type anode region and n-type cathode region) having the same value of resistance. Further, a diode portion containing poly-silicon having the same configuration as the temperature sensing portion can be used as a protective diode. Therefore, the degree of freedom in designing the diode using the poly-silicon layer is increased. According to the fourth embodiment, the ESD tolerance of the silicon carbide semiconductor device can be improved by the protective diode.

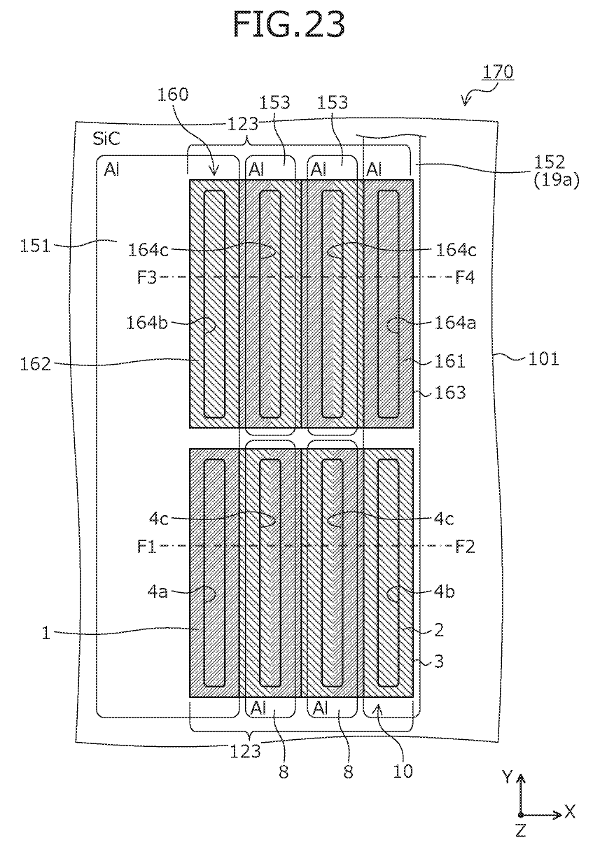

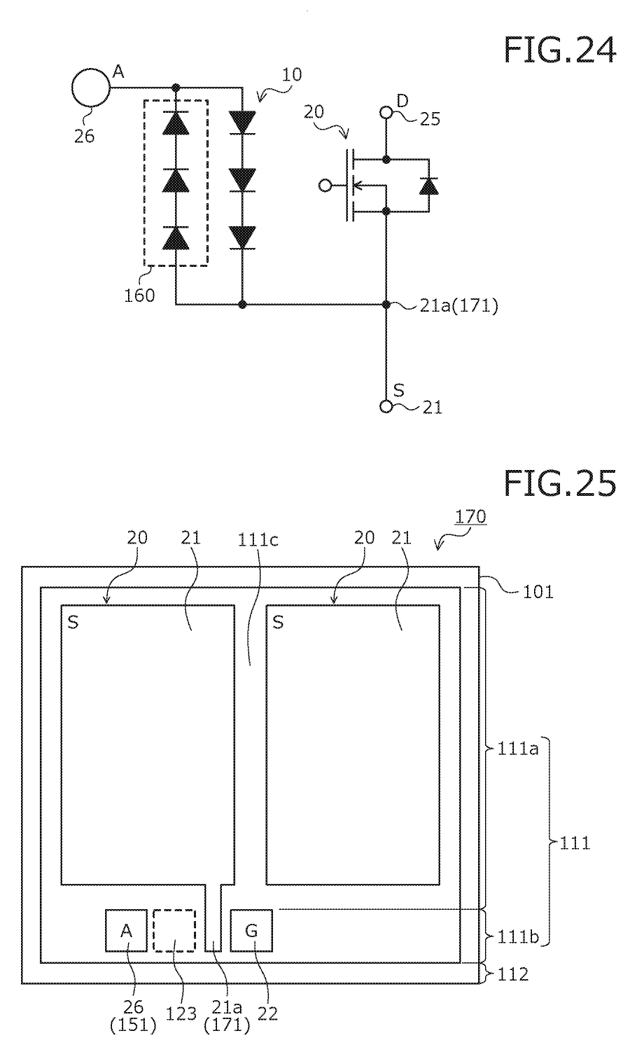

A silicon carbide semiconductor device according to a fifth embodiment will be described below. FIG. 23 is a plan view depicting a layout of the temperature sensing portion of the silicon carbide semiconductor device according to the fifth embodiment, as viewed from the front surface side of the semiconductor substrate. In FIG. 23, the p-type anode region 1, 161 and the n-type cathode region 2, 162 are indicated by different hatching. Cross-sectional views of the structure taken along cutting line F1-F2 and cutting line F3-F4 in FIG. 23 are the same as those in FIG. 22A and FIG. 22B, respectively. FIG. 24 is a circuit diagram depicting an equivalent circuit of the temperature sensing portion of FIG. 23. FIG. 25 is a plan view depicting a layout example of the silicon carbide semiconductor device according to the fifth embodiment, as viewed from the front surface side of the semiconductor substrate. In FIG. 23, the width (the width in the first direction X) of the cathode electrode 152 is depicted to be narrower than the width of the anode electrode 151 in accordance with FIG. 25.

The silicon carbide semiconductor device 170 according to the fifth embodiment depicted in FIGS. 23 to 25 is different from the silicon carbide semiconductor device 150 according to the fourth embodiment (see FIGS. 21, 22C, and 18) in that a surface electrode (electrode pad) common to the cathode electrode (cathode pad) of the temperature sensing portion 10 and the source electrode (source pad) of the main semiconductor device element 20 is provided. Here, a case where the source electrode 19 (see FIG. 4) and the source pad 21 of the main semiconductor device element 20 also serve as the cathode electrode 152 and the cathode pad 171 of the temperature sensing portion 10, respectively, will be described as an example. In the fifth embodiment, the configuration of the main semiconductor device element 20 is the same as that of the fourth embodiment except that the planar shapes of the source electrode 19 and the source pad 21 are different.

In the fifth embodiment, a portion (hereinafter, referred to as an extending portion) 19a of the source electrode 19 of the main semiconductor device element 20 extends to the main non-operating region 111b along one side of the diode region 123 having a substantially rectangular planar shape. In addition, the extending portion 19a of the source electrode 19 extends in the diode region 123 so as to face the n-type cathode region 2 of the pn junction diode on the most downstream side of the temperature sensing portion 10 (poly-silicon layer 3) and the p-type anode region 161 of the pn junction diode on the most upstream side (pn junction diode farthest from the anode terminal A) of the protective diode 160 (poly-silicon layer 163) in the depth direction Z, and is embedded in the contact holes 4b and 164a.

The configuration of the extending portion 19a of the source electrode 19 in the contact holes 4b and 164a is the same as that of the cathode electrode 152 of the fourth embodiment. A portion (hereinafter, referred to as an extending portion) 21a of the source pad 21 extends on the extending portion 19a of the source electrode 19 outside the diode region 123. The extending portion 19a of the source electrode 19 and the extending portion 21a of the source pad 21 also serve as the cathode electrode 152 and the cathode pad 171 of the temperature sensing portion 10, respectively. The cathode electrode 152 of the temperature sensing portion 10 also serves as the anode electrode of the protective diode 160 as in the fourth embodiment. The extending portion 21a of the source pad 21 may face the poly-silicon layer 163 in the depth direction Z.

The anode of the protective diode 160 is connected to the lowest potential point (the source of the main semiconductor device element 20) of the silicon carbide semiconductor device 170 by the cathode electrode 152 (FIG. 24). The configurations of the temperature sensing portion 10 and the protective diode 160 are the same as those of the fourth embodiment except that the cathode electrode 152 (cathode pad 171) is used as a surface electrode (electrode pad) common to the source electrode 19 (source pad 21). In FIG. 24, the protective diode 160 is inserted at a position farther from the source of the main semiconductor device element 20 than the temperature sensing portion 10, but the protective diode 160 may be inserted between the cathode of the temperature sensing portion 10 and the source of the main semiconductor device element 20.

Instead of the extending portion 19a of the source electrode 19 and the extending portion 21a of the source pad 21 serving as the cathode electrode 152 and the cathode pad 171 of the temperature sensing portion 10, respectively, the extending portion 19a of the source electrode 19 and the extending portion 21a of the source pad 21 may serve as the anode electrode and the anode pad of the temperature sensing portion 10, respectively. Even when either the anode or the cathode of the temperature sensing portion 10 is connected to the source of the main semiconductor device element 20, the temperature sensing portion 10 is fixed to the lowest potential (for example, the ground potential) of the main semiconductor device element 20 and thus, the operation of the temperature sensing portion 10 can be stabilized.

As described above, according to the fifth embodiment, effects similar to those of the first to fourth embodiments can be obtained. According to the fifth embodiment, since the surface electrode and the electrode pad common to the main semiconductor device element and the temperature sensing portion can be provided, the number of metal wiring layers on the semiconductor substrate can be reduced.

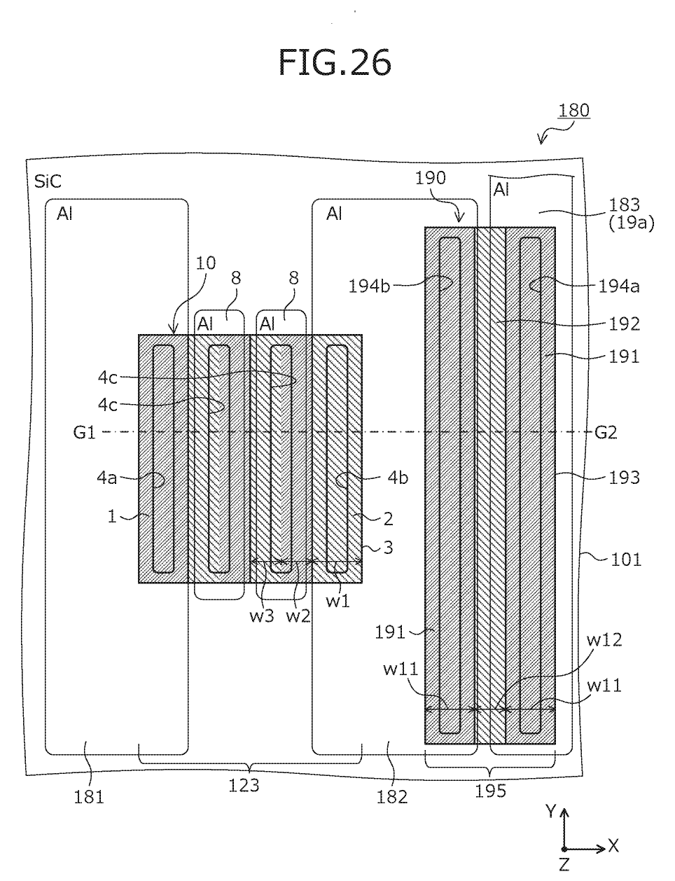

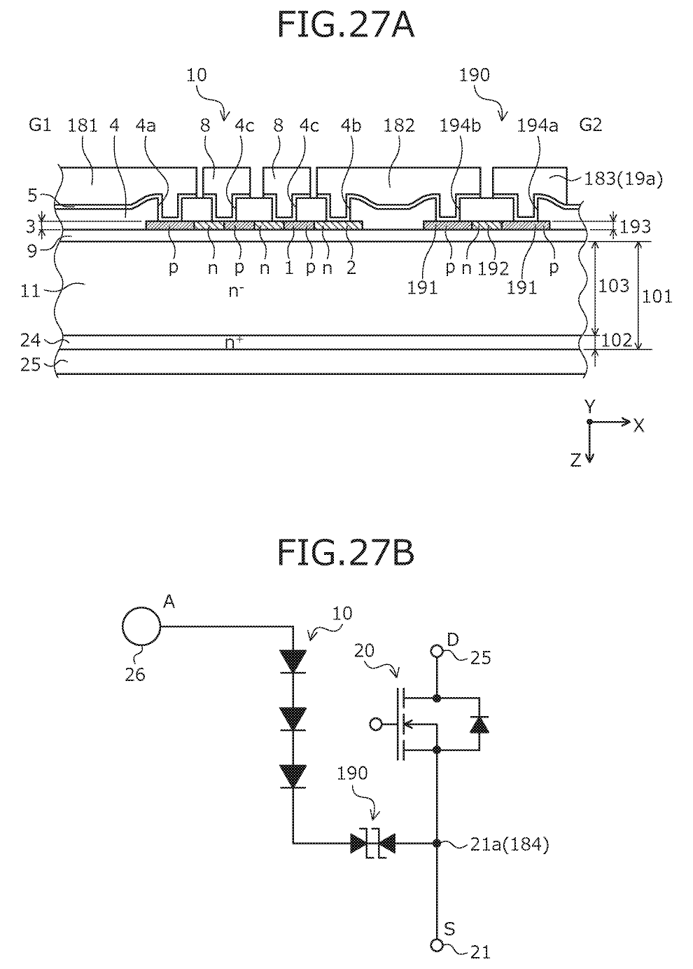

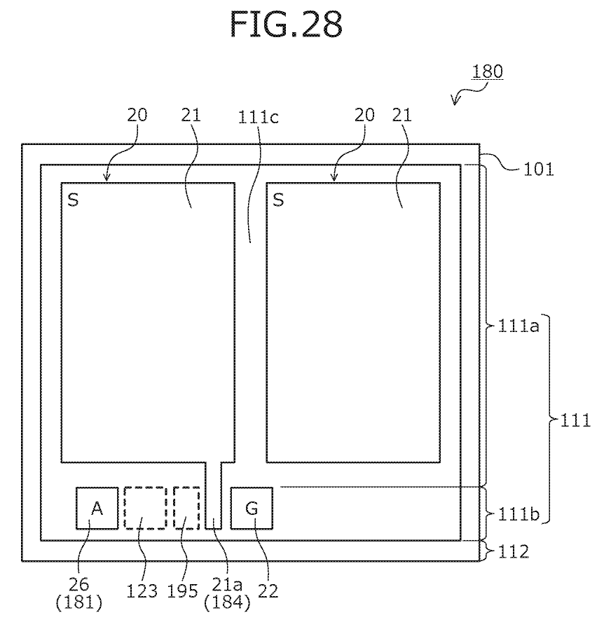

A silicon carbide semiconductor device according to a sixth embodiment will be described below. FIG. 26 is a plan view depicting a layout of the temperature sensing portion of the silicon carbide semiconductor device according to the sixth embodiment, as viewed from the front surface side of the semiconductor substrate. FIG. 27A is a cross-sectional view depicting a structure, along a cutting line G1-G2 in FIG. 26. In FIGS. 26 and 27A, the p-type anode regions 1, 191 and the n-type cathode regions 2, 192 are indicated by different hatching. FIG. 27B is a circuit diagram depicting an equivalent circuit of the temperature sensing portion of FIG. 26. FIG. 28 is a plan view depicting a layout example of the silicon carbide semiconductor device according to the sixth embodiment, as viewed from the front surface side of the semiconductor substrate.

A silicon carbide semiconductor device 180 according to the sixth embodiment depicted in FIGS. 26, 27A, 27B, and 28 is obtained by adding a bidirectional Zener diode (first diode) 190 to the silicon carbide semiconductor device 100 according to the first embodiment (see FIGS. 1, 2A, and 2B). The bidirectional Zener diode 190 is inserted between the source of the main semiconductor device element 20 and the cathode of the temperature sensing portion 10 (FIG. 27B). The bidirectional Zener diode 190 is a protective diode having a function of protecting the silicon carbide semiconductor device 180 from a high voltage exceeding the ESD tolerance by clamping a voltage exceeding a predetermined voltage (absolute value) using the reverse characteristics of the Zener diode.

In the bidirectional Zener diode 190, two Zener diodes are connected in series in opposite directions and thus, a voltage is clamped by a Zener diode in a reverse bias state among the two Zener diodes. Therefore, the bidirectional Zener diode 190 clamps a voltage exceeding the maximum value (=|±(Zener voltage+forward voltage)|) of the protection voltage in both directions. In the sixth embodiment, the configuration of the main semiconductor device element 20 (see FIG. 4) is similar to that of the first embodiment. The configuration of the temperature sensing portion 10 (FIGS. 26 and 27A) is similar to that of the first embodiment except for the shapes of the anode electrode 181 and the cathode electrode 182 in a plan view.

The bidirectional Zener diode 190 is formed over the entire poly-silicon layer 193 provided on the front surface of the semiconductor substrate 101 via the interlayer insulating film 9 and includes two lateral Zener diodes connected in series in opposite directions. The poly-silicon layer 193 configuring the bidirectional Zener diode 190 is disposed apart from the poly-silicon layer 3 configuring the temperature sensing portion 10, and faces the n-type cathode region 2 of the pn junction diode on the most downstream side of the temperature sensing portion 10 in the direction (here, the first direction X) in which the pn junction diodes (the p-type anode region 1 and the n-type cathode region 2) configuring the temperature sensing portion 10 are adjacent to each other in a plan view.

The p-type anode regions 191 of the two Zener diodes constituting the bidirectional Zener diode 190 and one n-type cathode region 192 common to the two Zener diodes are provided in the poly-silicon layer 193. The p-type anode region 191 of one Zener diode, the n-type cathode region 192 common to the two Zener diodes, and the p-type anode region 191 of the other Zener diode are adjacent to each other in the first direction X in this order, extend linearly in the second direction Y with substantially the same length, and are arranged in a stripe pattern. The thickness of the poly-silicon layer 193 is substantially the same as the thickness of the poly-silicon layer 3.

The p-type anode region 191 and the n-type cathode region 192 are selectively formed in the poly-silicon layer 193 by ion implantation. The dopant concentrations of the p-type anode region 191 and the n-type cathode region 192 are substantially the same as the dopant concentrations of the p-type anode region 1 and the n-type cathode region 2 in the poly-silicon layer 3 constituting the temperature sensing portion 10, respectively. Therefore, in the method of manufacturing the silicon carbide semiconductor device 100 according to the first embodiment, by appropriately changing the patterns of the ion implantation masks for forming the p-type anode region 1 and the n-type cathode region 2, the p-type anode region 191 and the p-type anode region 1 can be simultaneously formed, and the n-type cathode region 192 and the n-type cathode region 2 can be simultaneously formed.

The value of resistance of the bidirectional Zener diode 190 can be adjusted by a width w12 in the first direction X of the n-type cathode region 192. Although not particularly limited, for example, in the temperature sensing portion 10, the width w1 in the first direction X of the n-type cathode region 2 of the pn junction diode on the most downstream side is set to about 55 μm, and the widths w2 and w3 in the first direction X of the p-type anode region 1 and the n-type cathode region 2 electrically connected to the connecting electrode 8 are set to about 36 μm and about 32 μm, respectively. In this case, in the bidirectional Zener diode 190, a width w11 of the p-type anode region 191 in the first direction X may be about 50 μm, and the width w12 of the n-type cathode region 192 in the first direction X may be about 18 μm.

The length of the bidirectional Zener diode 190 (poly-silicon layer 193) in the second direction Y (that is, the length of the p-type anode region 191 and the n-type cathode region 192 extending in the second direction Y) is set such that the pn junction capacitance between the p-type anode region 191 and the n-type cathode region 192 of each of the two Zener diodes is obtained within a range necessary for the ESD tolerance of the silicon carbide semiconductor device 180 and within a range not adversely affecting the normal operation of the main semiconductor device element 20. Specifically, for example, when the length of the bidirectional Zener diode 190 in the second direction Y is about 500 μm or more, the capacitance of the bidirectional Zener diode 190 is not less than about 5 pF but not more than 10 pF (the alternating current flowing through the bidirectional Zener diode 190 is about 1 MHz).

The length of the bidirectional Zener diode 190 in the second direction Y may be longer than the length of the temperature sensing portion 10 (poly-silicon layer 3) in the second direction Y. The poly-silicon layers 193 and 3 are covered by the interlayer insulating film 4, and the interlayer insulating film 4 is interposed between the poly-silicon layer 193 and the poly-silicon layer 3. The poly-silicon layers 193 and 3 are electrically insulated from the semiconductor substrate 101 and other elements formed on the semiconductor substrate 101 by the interlayer insulating films 9 and 4. A field oxide film (not depicted) may be provided between the interlayer insulating film 9 and the semiconductor substrate 101 immediately below the poly-silicon layers 193 and 3.

The interlayer insulating film 4 is provided with contact holes 4a to 4c at positions facing the poly-silicon layer 3 in the depth direction Z, as in the first embodiment. The interlayer insulating film 4 is provided with contact holes 194a and 194b penetrating through the interlayer insulating film 4 in the depth direction Z and reaching the poly-silicon layer 193. Of the p-type anode regions 191 of the two Zener diodes constituting the bidirectional Zener diode 190, the p-type anode region 191 electrically connected to the source electrode 19 of the main semiconductor device element 20 is exposed in the contact hole 194a. The n-type cathode region 2 of the pn junction diode on the most downstream side of the temperature sensing portion 10 is exposed in the contact hole 194b.

In the temperature sensing portion 10, the connecting electrode 8 and the poly-silicon layer 3 are disposed in the diode region 123. The configuration of the anode electrode 181 is the same as that of the anode electrode 6 of the first embodiment. The anode electrode 181 is disposed across the diode region 123 from the outside of the diode region 123 similarly to the anode electrode 121 of the second embodiment. The length of the anode electrode 181 in the second direction Y may be the same as the length of the cathode electrode 182 in the second direction Y. The anode pad 26 faces the anode electrode 181 in the depth direction Z outside the diode region 123 and is electrically connected to the anode electrode 181.

Similarly to the cathode electrode 122 of the second embodiment, the cathode electrode 182 is embedded in the contact hole 4b in the diode region 123 and is electrically connected to the temperature sensing portion 10 (poly-silicon layer 3). In addition, the cathode electrode 182 is disposed across the diode region 123 and a Zener diode region 195 described later and is embedded in the contact hole 194b in the Zener diode region 195. The cathode electrode 182 is electrically connected to one p-type anode region 191 of the bidirectional Zener diode 190 in the contact hole 194b.

The length of the cathode electrode 182 in the second direction Y is set according to the length of the poly-silicon layer 193 in the second direction Y, and is longer than the length of the poly-silicon layer 3 in the second direction Y. The configuration of the cathode electrode 182 is the same as that of the cathode electrode 7 of the first embodiment except for the length in the second direction Y and the cathode electrode 182 being electrically connected to the bidirectional Zener diode 190 (poly-silicon layer 193). The configuration of the cathode electrode 182 in the contact hole 4b is the same as that of the cathode electrode 7 of the first embodiment. The configuration of the cathode electrode 182 in the contact hole 4b and the configuration of the cathode electrode 182 in the contact hole 194b are preferably the same. The cathode pad of the temperature sensing portion 10 is not provided.

The poly-silicon layer 193 of the bidirectional Zener diode 190 is disposed between the diode region 123 and a connecting pad 184 described later (hereinafter referred to as a Zener diode region 195). The extending portion 19a of the source electrode 19 of the main semiconductor device element 20 extends to the main non-operating region 111b along one side of the Zener diode region 195 having a substantially rectangular planar shape, and faces the other p-type anode region 191 of the bidirectional Zener diode 190 in the depth direction Z. The extending portion 19a of the source electrode 19 is embedded in the contact hole 194a and electrically connected to the other p-type anode region 191 of the bidirectional Zener diode 190.

The configuration of the extending portion 19a of the source electrode 19 in the contact hole 194a may be the same as the configuration of the cathode electrode 182 in the contact hole 194b. The extending portion 21a of the source pad 21 extends on the extending portion 19a of the source electrode 19 outside the Zener diode region 195. The Zener diode region 195 is not provided with an electrode pad and is covered by a passivation film. The extending portion 21a of the source pad 21 may be located on the extending portion 19a of the source electrode 19 in the Zener diode region 195. The extending portion 19a of the source electrode 19 and the extending portion 21a of the source pad 21 are a connecting electrode 183 and the connecting pad 184 for electrically connecting the other p-type anode region 191 of the bidirectional Zener diode 190 to the source electrode 19 of the main semiconductor device element 20, respectively.

The width of the connecting electrode 183 in the first direction X is set based on the maximum value of the forward current flowing through the temperature sensing portion 10 and the maximum value of the alternating current flowing through the bidirectional Zener diode 190 (the forward currents of the two Zener diodes). Although not particularly limited, for example, when it is assumed that the forward current flowing through the temperature sensing portion 10 is not less than about 0.1 mA but not more than 5 mA and the maximum value of the current rate of change di/dt of the forward current flowing through the Zener diode of the bidirectional Zener diode 190 at the time of ESD occurrence is about 100 mA/sec, the width of the connecting electrode 183 in the first direction X is set to not less than about 20 μm but not more than 100 μm, for example.

In the sixth embodiment, since the silicon carbide semiconductor device 180 is provided with the bidirectional Zener diode 190, even when the silicon carbide semiconductor device 180 is provided with the protective diode 160, the temperature T of the main semiconductor device element 20 can be detected using the voltage drop VR caused by the reverse current flowing through the temperature sensing portion 10. Therefore, the temperature T of the main semiconductor device element 20 is detected using the voltage drop VF due to the forward current flowing through the temperature sensing portion 10 or using the voltage drop VR due to the reverse current flowing through the temperature sensing portion 10 during the operation of the silicon carbide semiconductor device 180 (during the period in which the drain-source of the main semiconductor device element 20 is forward biased).

The second embodiment (see FIG. 16) may be applied to the silicon carbide semiconductor device 180 according to the sixth embodiment, and multiple temperature sensing portions 10 connected in parallel and having the same structure may be arranged. The third embodiment (see FIG. 21) may be applied to the silicon carbide semiconductor device 180 according to the sixth embodiment, and the temperature sensing portion 10 may be replaced with the temperature sensing portion 140 of the third embodiment.

As described above, according to the sixth embodiment, effects similar to those of the first to third embodiments can be obtained. According to the sixth embodiment, the diode portions (temperature sensing portion, bidirectional Zener diode) having different functions by poly-silicon can be formed by the poly-silicon layers (p-type anode region and n-type cathode region) having the same value of resistance. Therefore, the degree of freedom in designing the diode using the poly-silicon layer is increased. In addition, the number of metal wiring layers on the semiconductor substrate can be reduced by sharing the surface electrodes and the electrode pads electrically connected to the diode portion and the semiconductor device element as much as possible.

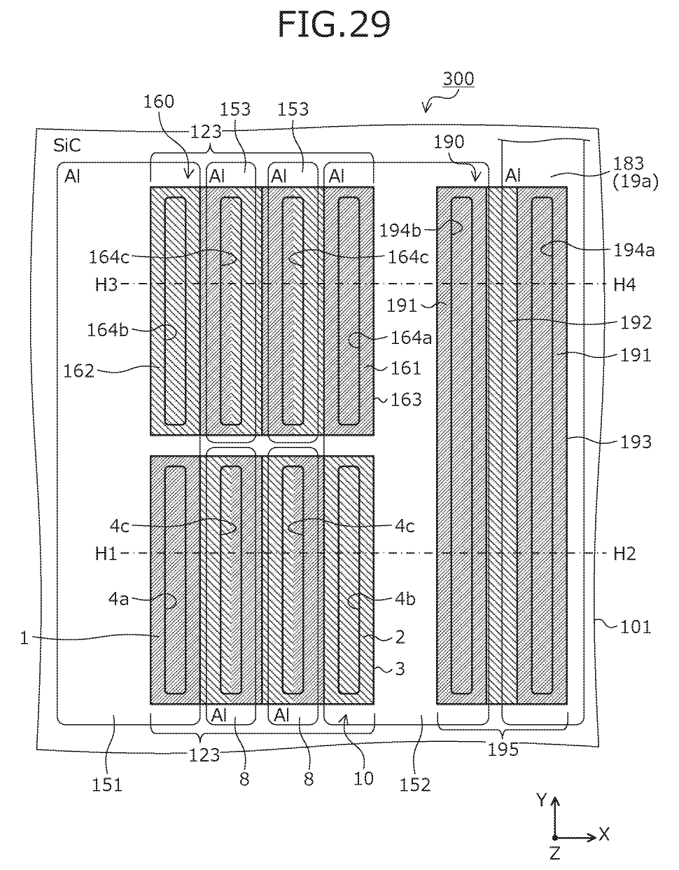

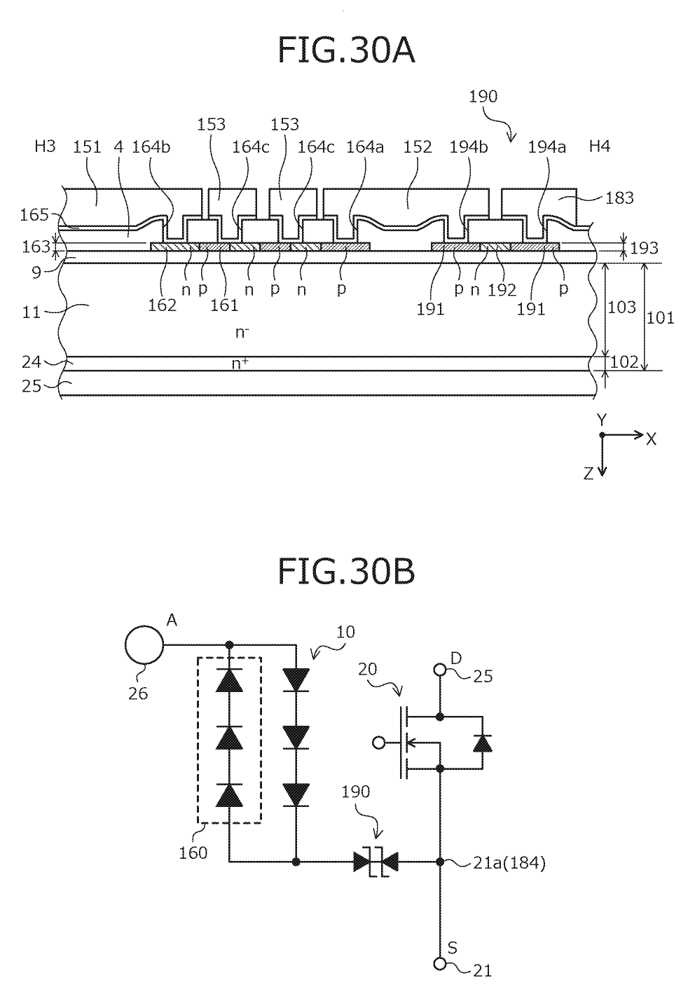

A silicon carbide semiconductor device according to a seventh embodiment will be described below. FIG. 29 is a plan view depicting a layout of the temperature sensing portion of the silicon carbide semiconductor device according to the seventh embodiment, as viewed from the front surface side of the semiconductor substrate. FIG. 30A is a cross-sectional view depicting a structure taken along cutting line H3-H4 in FIG. 29. The cross-sectional view of the structure along the line H1-H2 in FIG. 29 is the same as that in FIG. 27A. In FIGS. 29 and 30A, the p-type anode regions 1,191 and the n-type cathode regions 2, 192 are indicated by different hatching. FIG. 30B is a circuit diagram depicting an equivalent circuit of the temperature sensing portion of FIG. 29. A layout example of the silicon carbide semiconductor device 300 according to the seventh embodiment when viewed from the front surface side of the semiconductor substrate is similar to that of the sixth embodiment (see FIG. 28).

A silicon carbide semiconductor device 300 according to the seventh embodiment depicted in FIGS. 29, 30A, and 30B is obtained by adding a bidirectional Zener diode 190 to the silicon carbide semiconductor device 150 according to the fourth embodiment (see FIGS. 21, 22A, and 22B). The bidirectional Zener diode 190 is inserted between the source of the main semiconductor device element 20 and the cathode of the temperature sensing portion 10 (FIG. 30B). In the seventh embodiment, the configurations of the main semiconductor device element 20 (see FIG. 4), the temperature sensing portion 10 (FIG. 29), and the protective diode 160 (FIGS. 29 and 30A) are similar to those of the fourth embodiment. The configuration of the bidirectional Zener diode 190 (FIGS. 29 and 30A) is the same as that of the sixth embodiment except that the bidirectional Zener diode 190 is electrically connected to the anode of the protective diode 160.

Therefore, the poly-silicon layer 3 constituting the temperature sensing portion 10, the poly-silicon layer 163 constituting the protective diode 160, and the poly-silicon layer 193 constituting the bidirectional Zener diode 190 are disposed apart from each other on the interlayer insulating film 9 on the front surface of the semiconductor substrate 101. The poly-silicon layer 163 faces the poly-silicon layer 3 in the second direction Y as in the fourth embodiment. The poly-silicon layer 193 faces, in the first direction X, the n-type cathode region 2 of the most downstream pn junction diode of the temperature sensing portion 10 (poly-silicon layer 3) and the p-type anode region 161 of the most upstream pn junction diode (pn junction diode farthest from the anode terminal A) of the protective diode 160 (poly-silicon layer 163).

The poly-silicon layers 3, 163, and 193 are covered by the interlayer insulating film 4. The interlayer insulating film 4 is interposed between the poly-silicon layer 3 and the poly-silicon layer 163, between the poly-silicon layer 3 and the poly-silicon layer 193, and between the poly-silicon layer 163 and the poly-silicon layer 193. The poly-silicon layers 3, n163, and 193 are electrically insulated from the semiconductor substrate 101 and other elements formed on the semiconductor substrate 101 by the interlayer insulating films 9 and 4. The interlayer insulating film 4 is provided with contact holes 4a to 4c and 164a to 164c as in the fourth embodiment. The interlayer insulating film 4 is provided with contact holes 194a and 194b as in the sixth embodiment.

The configuration of the anode electrode 151 of the temperature sensing portion 10 is the same as that of the fourth embodiment. Similarly to the fourth embodiment, the cathode electrode 152 of the temperature sensing portion 10 is electrically connected to the n-type cathode region 2 of the most downstream pn junction diode of the temperature sensing portion 10 in the contact hole 4b, and is electrically connected to the p-type anode region 161 of the most upstream pn junction diode of the protective diode 160 in the contact hole 164a. Further, the cathode electrode 152 is electrically connected to one p-type anode region 191 of the bidirectional Zener diode 190 in the contact hole 194b similarly to the cathode electrode 182 of the sixth embodiment.

The connecting electrode 8 and the poly-silicon layer 3 of the temperature sensing portion 10 and the connecting electrode 153 and the poly-silicon layer 163 of the protective diode 160 are arranged in the diode region 123 as in the fourth embodiment. The configuration of the anode electrode 151 is the same as that of the fourth embodiment. The cathode electrode 152 and the poly-silicon layer 193 are arranged in the Zener diode region 195 (see FIG. 28) similarly to the cathode electrode 182 and the poly-silicon layer 193 of the sixth embodiment. The arrangement of the bidirectional Zener diode 190 is the same as that in the sixth embodiment. The configurations of the connecting electrode 183 and the connecting pad 184 of the bidirectional Zener diode 190 are the same as those in the sixth embodiment.

The second embodiment (see FIG. 16) may be applied to the silicon carbide semiconductor device 300 according to the seventh embodiment, and multiple temperature sensing portions 10 connected in parallel and having the same structure may be arranged. The third embodiment (see FIG. 21) may be applied to the silicon carbide semiconductor device 300 according to the seventh embodiment, the temperature sensing portion 10 may be replaced with the temperature sensing portion 140 of the third embodiment, and the protective diode 160 may be replaced with the same configuration as the temperature sensing portion 140 of the third embodiment.

As described above, according to the seventh embodiment, effects similar to those of the first to sixth embodiments can be obtained. According to the seventh embodiment, the poly-silicon layers (p-type anode region and n-type cathode region) having the same value of resistance can provide the silicon carbide semiconductor device with multiple protective functions (protective diode, bidirectional Zener diode).

The present disclosure is not limited to the embodiments described above, and various modifications can be made without departing from the spirit of the present disclosure.

According to the silicon carbide semiconductor device and the method of manufacturing the silicon carbide semiconductor device according to the present disclosure, there is an effect in that temperature detection accuracy can be improved.

As described above, the silicon carbide semiconductor device and the method of manufacturing the silicon carbide semiconductor device according to the present disclosure are useful for in-vehicle applications in which there is a period of operation in a low-temperature state, and are particularly suitable for a switching element such as a MOSFET.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device comprising:
a semiconductor substrate containing silicon carbide;
a semiconductor device element provided on the semiconductor substrate;
a poly-silicon layer provided on a main surface of the semiconductor substrate via an insulating film, the poly-silicon layer including a p-type first poly-silicon layer and an n-type second poly-silicon layer forming a pn junction therebetween; and
a diode formed by the pn junction, wherein
the second poly-silicon layer contains phosphorus or antimony as a donor, and is so configured that a sheet resistance thereof at 25 degrees C is not less than 80 Ω/□ but not more than 400 Ω/□.

2. The semiconductor device according to claim 1, wherein
the first poly-silicon layer contains boron or indium as an acceptor, and is so configured that a sheet resistance thereof at 25 degrees C is not less than 50Ω/□ but not more than 170Ω/□.

3. The semiconductor device according to claim 1, wherein the poly-silicon layer has a thickness of not less than 300 nm but not more than 600 nm.

4. The semiconductor device according to claim 1, wherein the diode is configured to detect a temperature of the semiconductor device element based on a rate of change of a difference in potential between two ends of the diode with respect to a temperature change of the semiconductor device element.

5. The semiconductor device according to claim 1, wherein the semiconductor device element is a metal oxide semiconductor field effect transistor (MOSFET).

6. A semiconductor device, comprising:
a semiconductor substrate containing silicon carbide;
a semiconductor device element provided on the semiconductor substrate,
a plurality of poly-silicon layers provided, apart from one another, on a main surface of the semiconductor substrate via an insulating film, each poly-silicon layer including a p-type first poly-silicon layer and an n-type second poly-silicon layer forming a pn junction therebetween; and
a plurality of diodes formed by the pn junctions in the plurality of the poly-silicon layers, the plurality of diodes including a first diode and a second diode different from each other, wherein
said first diode is either connected in antiparallel to the second diode, or connected between a lowest potential point of the semiconductor device element and a cathode of the second diode.

7. The semiconductor device according to claim 6, wherein
the first diode is connected in antiparallel to the second diode, and
the semiconductor device further includes a surface electrode provided on the main surface thereof and electrically connected to the lowest potential point of the semiconductor device element and the cathode of the second diode.

8. The semiconductor device according to claim 7, wherein the first diode is a protective diode that conducts when a transient voltage exceeding a Zener voltage is applied thereto, and that protects the semiconductor device element from the transient voltage by leading outside the semiconductor device, a current generated by the transient voltage.

9. The semiconductor device according to claim 6, wherein
the first diode is a bidirectional Zener diode connected between the lowest potential point of the semiconductor device element and the cathode of the second diode, the bidirectional Zener diode having two anodes, and
the semiconductor device further includes:
a first surface electrode provided on the main surface thereof and electrically connected to the cathode of the second diode and one of the two anodes of the first diode, and
a second surface electrode provided on the main surface thereof and electrically connected to the lowest potential point of the semiconductor device element and the other of the two anodes of the first diode.

10. The semiconductor device according to claim 9, wherein
the first diode is formed by two Zener diodes connected in series in opposite directions in the poly-silicon layer.

11. The semiconductor device according to claim 10, wherein a dopant concentration of the first poly-silicon layer constituting the first diode is equal to a dopant concentration of the first poly-silicon layer constituting the second diode.

12. The semiconductor device according to claim 10, wherein a dopant concentration of the second poly-silicon layer constituting the first diode is equal to a dopant concentration of the second poly-silicon layer constituting the second diode.

13. The semiconductor device according to claim 10, wherein the first diode is a protective diode that protects the semiconductor device element from a transient voltage exceeding a predetermined voltage by clamping the transient voltage using a reverse characteristic of the bidirectional Zener diode.

14. The semiconductor device according to claim 6, wherein
the first diode is formed of two diodes, one connected in antiparallel to the second diode and another connected between the lowest potential point of the semiconductor device element and the cathode of the second diode.

15. The semiconductor device according to claim 6, wherein the second diode is configured to detect a temperature of the semiconductor device element based on a rate of change of a difference in potential between two ends of the second diode with respect to a temperature change of the semiconductor device element.

16. A method of manufacturing a semiconductor device, the method comprising:
preparing a semiconductor substrate containing silicon carbide;
forming in the semiconductor substrate a semiconductor device element;
forming a poly-silicon layer on a main surface of the semiconductor substrate via an insulating film;
ion-implanting a p-type dopant into the poly-silicon layer, thereby forming a first poly-silicon layer;
ion-implanting an n-type dopant into the poly-silicon layer, thereby forming a second poly-silicon layer, the first poly-silicon layer and the second poly-silicon layer forming a pn junction therebetween, to thereby form a diode; and
performing a heat treatment thereby activating the p-type dopant and the n-type dopant as an acceptor and a donor, respectively, wherein
the ion-implanting the n-type dopant includes:
ion-implanting phosphorus with a net dose amount of not less than 1.0×10¹⁵/cm² but not more than 1.0×10¹⁶/cm² or
ion-implanting antimony with a net dose amount of not less than 1.5×10¹⁵/cm² but not more than 2.5×10¹⁵/cm².

17. The method according to claim 16, wherein
the ion-implanting the p-type dopant includes:
ion-implanting boron with a net dose amount of not less than 7.0×10¹⁴/cm² but not more than 1.0×10¹⁶/cm² or
ion-implanting indium with a net dose amount of not less than 4.0×10¹⁴/cm² but not more than 7.0×10¹⁴/cm².

18. The method according to claim 16, wherein a temperature of the heat treatment is set within a range of 1050 degrees C to 1200 degrees C.

19. The method according to claim 16, wherein in the forming of the poly-silicon layer, the thickness of the poly-silicon layer is set to be not less than 300 nm but not more than 600 nm.

20. The method according to claim 16, wherein the diode is configured to detect a temperature of the semiconductor device element based on a rate of change of a difference in potential between the ends of the diode with respect to a temperature change of the semiconductor device element.
